(19) United States
(12) Patent Application Publication
(10) Pub. No.: US 2008/0223521 A1
(43) Pub. Date: Sep. 18, 2008

(54) Plasma Source Coil and Plasma Chamber Using the Same

(76) Inventors: Nam Hun Kim, Gyeonggi-do (KR); Do Hyung Lee, Cupertino, CA (US); Young Kun Oh, Seoul (KR)

Correspondence Address: MORGAN & FINNEGAN, L.L.P., 3 WORLD FINANCIAL CENTER, NEW YORK, NY, 10281-2101, US

(21) Appl. No.: 10/599,229

(22) PCT Filed: Mar. 29, 2005
(86) PCT No.: PCT/KR2005/000912

§ 371 Date: Sep. 22, 2006

(30) Foreign Application Priority Data
Mar. 30, 2004 (KR) 10-2004-0021576
Mar. 30, 2004 (KR) 10-2004-0021577
Mar. 30, 2004 (KR) 10-2004-0021578

(51) Int. Cl. H01L 21/3065

(52) U.S. Cl. 156/345.1

(57) ABSTRACT

A plasma source coil includes a bushing arranged at a center part, and a plurality of unit coils arranged in the form of a concentric circle from a circumference of the bushing on the bases of the bushing. One end of each unit coil and one end of the bushing are commonly connected to a power-supply terminal, and the other end of each unit coil and the other end of the bushing are commonly connected to a ground terminal.

### TECHNICAL FIELD

The present invention relates to an apparatus for manufacturing a semiconductor device, and more particularly to a plasma source coil for providing uniform distribution of a Critical Dimension (CD) change rate, and a plasma chamber using the same.

### BACKGROUND ART

In the last 20 years, techniques for manufacturing Ultra-Large Scale Integrate (ULSI) circuit components have been rapidly developed. The development of a variety of semiconductor fabrication devices capable of supporting fabrication techniques requiring the ultimate techniques has enabled the rapid development of ULSI circuit components. Plasma chambers from among the above-mentioned semiconductor fabrication devices have been used not only for general etching processes but also for deposition processes, such that their range of applications has rapidly increased.

A plasma chamber is indicative of semiconductor fabrication equipment, which can artificially form plasma in a reaction space, and can perform a variety of processes such as etching and deposition using the formed plasma. The above-mentioned plasma chamber can be classified into Electron Cyclotron Resonance (ECR) sources, Helicon-Wave Excited Plasma (HWEP) sources, Capacitively Coupled Plasma (CCP) sources, and Inductively Coupled Plasma (ICP) sources, etc. The ICP plasma sources provide an induction coil with Radio Frequency (RF) power so as to generate a magnetic field, and confine electrons in an internal center part of a chamber by an electric field induced by the magnetic field, such that high-density plasma is generated even at low pressure. Compared with ECR plasma sources or HWEP sources, the ICP sources have simpler structure, and can acquire large-area plasma using a relatively easy method, such that they are widely used in various applications.

In a process for processing a semiconductor wafer using a plasma source coil, for example, in an etching process, it is very important to guarantee uniform distribution of CD change rate. The CD change rate is the difference between expected CD and resultant CD. Particularly, the higher the difference between a CD at the center part of a wafer and the other CD at the edge of the wafer, the lower the productivity. Generally, it is well known in the art that the CD at the edge of the wafer is higher than the CD at the center part of the wafer. However, difference between the CD at the edge of the wafer and that at the center part of the wafer can be controlled by variables such as the etching gas used. In conclusion, there is a need to minimize a difference between the CD at the edge of the wafer edge and that at the center part of the wafer. Particularly, the higher the degree of integration of a device, the higher the above-mentioned necessity.

Presently, there have been widely used a variety of methods for adjusting process parameters (e.g., pressure, gas supply, gas type, power, and temperature, etc.) to adjust the distribution of CD. However, indeed, there is a limitation in adjusting the CD distribution using the above-mentioned methods, and there is no method capable of providing satisfactory results.

Particularly, as semiconductor fabrication has recently moved from a 20 mm wafer process to a 300 mm wafer process, application of general ICP sources is limited due to structural problems. In the case of a plasma chamber for generally adapting the ICP sources, high RF current flows in a coil constructing an inductor of a resonance circuit. This RF current capacity greatly affects distribution of plasma generated in a chamber. It is well known in the art that a coil constructing an inductor includes unique resistance therein. Therefore, when current flows in the coil, as the length of the current flow is longer along the coil, energy consumption occurs by unique resistance of the coil such that the consumed energy is converted into thermal energy. As a result, the current capacity flowing in the coil may be gradually reduced. In this way, if the current capacity flowing in the coil is uneven, the distribution of plasma generated in the chamber may also be uneven. The above-mentioned phenomenon becomes more serious in the case of a conventional single coil. In other words, in a plasma source coil formed of a single coil, the longer the coil the higher the resistance of the coil, such that current density for plasma induction is also gradually lowered. In order to solve the above-mentioned problems, there has been recently proposed a plasma source coil in which a plurality of coils are arranged in parallel.

FIG. 1 is a schematic diagram of a plasma chamber including a plasma source coil in which coils are arranged in parallel. FIG. 2 is a detailed illustration of the plasma source coil shown in FIG. 1.

Referring to FIGS. 1 and 2, the plasma chamber 100 includes a reaction space 104, which is defined by an exterior wall 102 of the chamber and a dome 112 of the chamber. Plasma 110 is formed in a predetermined area of the reaction space 104 under predetermined conditions. Although the reaction space 104 is open at a lower part of the plasma chamber 100 as shown in FIG. 1, this illustration is provided only to simplify the drawings. Indeed, a lower part of the plasma chamber 100 is also isolated from an external part, such that a vacuum state can be maintained in an internal part of the plasma chamber 100. A wafer support 106 is arranged at a lower part of the plasma chamber 100. A semiconductor wafer 108 to be processed is seated on an upper surface of the wafer support 106. The wafer support 106 is connected to an external RF power-supply unit 114. The wafer support 106 may further include a heater therein (not shown in the drawings).

A plasma source coil for forming plasma 110 is arranged at an exterior surface of the dome 112. As shown in FIG. 2, the plasma source coil 120 includes four unit coils, i.e., first to fourth unit coils 121, 122, 123, and 124, which are connected in parallel. Although 4 unit coils are illustrated in the drawings, the number of unit coils may be freely selected as necessary. First to fourth unit coils 121, 122, 123, and 124 are each configured in the form of a circle having a predetermined radius. Particularly, the first unit coil 121 arranged at the center part of the plasma source coil has the smallest radius. The closer the circumference of the plasma source coil, the higher the radius in the order of the second unit coil 122->the third unit coil 123->the fourth unit coil 124. In conclusion, the first unit coil 121 is enclosed by the second unit coil 122, the second unit coil 122 is enclosed by the third unit coil 123, and the third unit coil 123 is enclosed by the fourth unit coil 124. The first to fourth unit coils 121, 122, 123, and 124 are connected in parallel to an RF power-supply unit 116. The first to fourth unit coils 121, 122, 123, and 124 are connected in parallel to a ground terminal.

The first to fourth unit coils 121, 122, 123, and 124 contained in the plasma chamber 100 receive RF power from the RF power-supply unit 116, such that an electric field of predetermined intensity is generated by the first to fourth unit coils 121, 122, 123, and 124. This electric field passes through the dome 112, and enters the reaction space 104. The electric field received in the reaction space 104 is discharged to gas contained in the reaction space 104, the gas is converted into plasma, and a chemical reaction between neutral radical particles generated by the gas converted into the plasma and charged ions occurs. Thereby, the surface of the semiconductor wafer 108 is processed. The first, second, third, and fourth unit coils 121, 122, 123, and 124 are connected in parallel, such that they can reduce impedance acting as resistance or inductance and can easily process a large-capacity semiconductor wafer.

However, there are a variety of problems regardless of the above-mentioned advantages. A representative problem is indicative of difficulty in adjusting selection ratio, etching rate, and an etching profile in the case of performing an etching process. For instance, it is well known in the art that selection ratio and etching rate are related inversely proportional (also called a trade-off relationship), but the etching profile is also not fixed. For example, a good etching profile is not generated at a low selection ratio and a low etching rate, whereas the good etching profile is generated at a high selection ratio and a low etching rate. The above-mentioned fact indicates that the CD change rate

### ΔCD

(i.e., a difference between expected CD and resultant CD) is high. Particularly, there is a disadvantage in that distribution of

### ΔCD

is not maintained constant due to the relatively high plasma density at the wafer center.

### DISCLOSURE OF INVENTION

### Technical Problem

Therefore, the present invention has been made in view of the above problems, and it is an object of the present invention to provide a plasma source coil indicative of uniform distribution of

### ΔCD

so as to process a large-capacity semiconductor wafer.

It is another object of the present invention to provide a plasma chamber using the plasma source coil.

### Technical Solution

In accordance with one aspect of the present invention, the above and other objects can be accomplished by the provision of a plasma source coil comprising: a bushing arranged at a center part; and a plurality of unit coils arranged in the form of a concentric circle from a circumference of the bushing on the basis of the bushing, wherein one end of each unit coil and one end of the bushing are commonly connected to a power-supply terminal, and the other end of each unit coil and the other end of the bushing are commonly connected to a ground terminal.

The bushing is formed of a conductive material.

The plurality of unit coils are each configured in the form of a circle.

The plurality of unit coils have a convex-type structure so that their position is lowered in proportion to a distance from the bushing. At least two unit coils arranged at the outermost position from among the plurality of unit coils are arranged on the same plane.

The plurality of unit coils have a concave-type structure so that their position is elevated in proportion to a distance from the bushing. At least two unit coils arranged at the outermost position from among the plurality of unit coils are arranged on the same plane.

In accordance with another aspect of the present invention, there is provided a plasma source coil comprising: a plurality of lower unit coils arranged in the form of a concentric circle on a first plane in a lower part; and a plurality of upper unit coils arranged in the form of a concentric circle on a second plane in an upper part, wherein one ends of the lower unit coils are commonly connected to a power-supply terminal and the other ends thereof are commonly connected to a ground terminal, and one ends of the upper unit coils are commonly connected to the power-supply terminal and the other ends thereof are commonly connected to the ground terminal.

A distance among the lower unit coils and a distance among the upper unit coils are each indicative of 0.5˜2 cm.

The lower unit coils and the upper unit coils are connected to each other via connection lines connected to the power-supply terminal and the other connection lines connected to the ground terminal.

In accordance with yet another aspect of the present invention, there is provided a plasma source coil comprising: a bushing vertically arranged in the form of a cylinder at a center part; a plurality of lower unit coils arranged in the form of a concentric circle on a first plane where the bottom of the bushing is located; and a plurality of upper unit coils arranged in the form of a concentric circle on a second plane where the top of the bushing is located, wherein one ends of the lower unit coils are commonly connected to a power-supply terminal and the other ends thereof are commonly connected to a ground terminal, and one ends of the upper unit coils are commonly connected to the power-supply terminal and the other ends thereof are commonly connected to the ground terminal.

The bushing is connected to the power-supply terminal and the ground terminal.

A distance among the lower unit coils and a distance among the upper unit coils are each indicative of 0.5˜2 cm.

The lower unit coils and the upper unit coils are connected to each other via connection lines connected to the power-supply terminal and the other connection lines connected to the ground terminal.

In accordance with yet another aspect of the present invention, there is provided a plasma source coil comprising: a plurality of unit coils arranged in the form of concentric circles having different radiuses while having a common center part, wherein one ends of the unit coils are commonly connected to a power-supply unit, the other ends thereof are commonly connected to a ground terminal, and the unit coils are connected to each other via at least one connection line.

In accordance with yet another aspect of the present invention, there is provided a plasma source coil comprising: a plurality of unit coils arranged in the form of concentric circles having different radiuses on the basis of a bushing arranged at a center part, wherein one ends of the unit coils are commonly connected to a power-supply unit, the other ends thereof are commonly connected to a ground terminal, and the unit coils are connected to each other via at least one connection line.

The plurality of unit coils have a convex-type structure so that their position is lowered in proportion to a distance from the bushing.

The plurality of unit coils have a concave-type structure so that their position is elevated in proportion to a distance from the bushing.

In accordance with yet another aspect of the present invention, there is provided a plasma source coil comprising: a plurality of lower unit coils arranged in the form of a concentric circle on a first plane in a lower part; and a plurality of upper unit coils arranged in the form of a concentric circle on a second plane in an upper part, wherein one ends of the lower unit coils are commonly connected to a power-supply terminal and the other ends thereof are commonly connected to a ground terminal, one ends of the upper unit coils are commonly connected to the power-supply terminal and the other ends thereof are commonly connected to the ground terminal, and the lower unit coils are connected to each other via at least one lower connection line, and the upper unit coils are connected to each other via at least one upper connection line.

In accordance with yet another aspect of the present invention, there is provided a plasma source coil comprising: a bushing vertically arranged in the form of a cylinder at a center part; a plurality of lower unit coils arranged in the form of a concentric circle on a first plane where the bottom of the bushing is located; and a plurality of upper unit coils arranged in the form of a concentric circle on a second plane where the top of the bushing is located, wherein one ends of the lower unit coils are commonly connected to a power-supply terminal and the other ends thereof are commonly connected to a ground terminal, and one ends of the upper unit coils are commonly connected to the power-supply terminal and the other ends thereof are commonly connected to the ground terminal, and the lower unit coils are connected to each other via at least one lower connection line, and the upper unit coils are connected to each other via at least one upper connection line.

In accordance with yet another aspect of the present invention, there is provided a plasma source coil comprising: a bushing arranged at a center part; and a plurality of unit coils, which are extended from the bushing, and are spirally wound on the bushing, wherein the unit coils have different surface areas in a first wafer area having a predetermined radius from a center part, a second wafer area enclosing the first wafer area, and a coil edge area enclosing the second wafer area.

The unit coils are arranged to have a predetermined turning number “n” calculated using a predetermined equation of n=a×(b/m) (where “a” and “b” are both positive integers, and “m” is indicative of the number of unit coils corresponding to an integer greater than “2”).

The surface areas of the unit coils are maintained constant, are gradually reduced, or are gradually increased, as a distance to an edge part in the first wafer area decreases.

The surface areas of the unit coils are gradually increased, are maintained constant, or are gradually reduced, as a distance to an edge part in the second wafer area decreases.

The surface areas of the unit coils are maintained constant, are gradually reduced, are gradually increased, or are gradually reduced, as a distance to an edge part in the coil edge area decreases.

The first wafer area and the second wafer area overlap a wafer surface to be processed.

A radius from a center part of the first wafer area to an edge part thereof is equal to or less than about 10˜30% of an entire radius of a wafer, a width of the second wafer area is equal to about 70˜90% of an entire radius of the wafer, and a width of the coil edge area is equal to about 30˜50% of an entire radius of the wafer.

The second wafer area includes a first area adjacent to the first wafer area and a second area adjacent to the coil edge area.

The degree of variation in surface area of each unit coil in the first area of the second wafer area is different from that in the second area of the second wafer area. A width of the first area of the second wafer area is about 60˜90% of a total width of the second wafer area, and a width of the second area of the second wafer area is about 10˜40% of the total width of the second wafer area.

In accordance with yet another aspect of the present invention, there is provided a plasma chamber comprising: an exterior wall and a dome for defining a reaction space in which plasma is formed; a support arranged at a lower part of the reaction space to support a semiconductor wafer to be processed; and a plasma source coil including a bushing arranged at a center part, a plurality of unit coils arranged in the form of a concentric circle from a circumference of the bushing on the basis of the bushing, wherein one end of each unit coil and one end of the bushing are commonly connected to a power-supply terminal, and the other end of each unit coil and the other end of the bushing are commonly connected to a ground terminal.

In accordance with yet another aspect of the present invention, there is provided a plasma chamber comprising: an exterior wall and a dome for defining a reaction space in which plasma is formed; a support arranged at a lower part of the reaction space to support a semiconductor wafer to be processed; a plasma source coil including a bushing arranged at a center part, a plurality of unit coils extended from the bushing while being spirally wound on the bushing, wherein the unit coils have different surface areas in a first wafer area having a predetermined radius from the center part on the dome, a second wafer area enclosing the first wafer area, and a coil edge area enclosing the second wafer area; a support rod arranged at a predetermined area of a center part of the bushing; and a power-supply unit connected to the support rod to provide the plasma source coil with power.

The unit coils are arranged to have a predetermined turning number “n” calculated using a predetermined equation of n=a×(b/m) (where “a” and “b” are both positive integers, and “m” is indicative of the number of unit coils corresponding to an integer greater than “2”).

The surface areas of the unit coils are maintained constant, are gradually reduced, or are gradually increased, as a distance to an edge part in the first wafer area decreases.

The surface areas of the unit coils are gradually increased, are maintained constant, or are gradually reduced, as a distance to an edge part in the second wafer area decreases.

The surface areas of the unit coils are maintained constant, are gradually reduced, are gradually increased, or are gradually reduced, as a distance to an edge part in the coil edge area decreases.

The first wafer area and the second wafer area overlap a wafer surface to be processed.

A radius from a center part of the first wafer area to an edge part thereof is equal to or less than about 10˜30% of an entire radius of a wafer, a width of the second wafer area is equal to about 70˜90% of an entire radius of the wafer, and a width of the coil edge area is equal to about 30˜50% of an entire radius of the wafer.

The second wafer area includes a first area adjacent to the first wafer area and a second area adjacent to the coil edge area.

The degree of variation in surface area of each unit coil in the first area of the second wafer area is different from that in the second area of the second wafer area. A width of the first area of the second wafer area is about 60˜90% of a total width of the second wafer area, and a width of the second area of the second wafer area is about 10˜40% of the total width of the second wafer area.

In accordance with yet another aspect of the present invention, there is provided a plasma apparatus comprising: a process chamber including a wafer; a bias power unit for providing a back surface of the wafer with bias power; a plasma source structure; and a source power unit for providing the plasma source coil structure with source power for generating the plasma. The plasma source coil structure which is disposed at the outside of an upper part of the process chamber to convert reaction gas contained in the process chamber into plasma, includes: a coil bushing arranged at a center part; and at least two unit coils, which are extended from the coil bushing, are spirally wound on the coil bushing. Therefore, as a distance from the center part to a radial edge increases, a distance between a coil positioned at a specific radial point and the other coil adjacent to the coil is gradually reduced, and is then increased.

The unit coils contained in the plasma source coil structure are wound on the coil bushing at a predetermined turning number of 1 or more.

An area of the plasma source coil structure is greater than an area of the wafer by about 50% or less.

The unit coils are wound to allow a specific position capable of providing a minimum distance among the unit coils to be included in the wafer area.

The specific position having the minimum distance among the coils is positioned adjacent to an edge part of the wafer area, whereby an area in which the distance among the coils is re-increased after passing through the specific position is less than the other area in which the distance among the coils is reduced.

### ADVANTAGEOUS EFFECTS

A plasma source coil and a plasma chamber using the same in accordance with a preferred embodiment of the present invention reduce resistance of a coil, and increase current density without increasing power, resulting in the enhancement of plasma density. Also, a plurality of unit coils are arranged in the form of various shapes, such that plasma density can be easily adjusted to enhance selection ratio, etching rate, and an etching profile, resulting in uniform distribution of

### ΔCD

.

A plasma source coil and a plasma chamber in accordance with another preferred embodiment of the present invention change a surface area of the plasma source coil capable of generating plasma according to position information, such that plasma density in the reaction space contained in the plasma chamber can be finely adjusted according to position information, resulting in uniform distribution of

### ΔCD

in the range from the center part of a wafer to the edge of the wafer.

A plasma chamber in accordance with yet another preferred embodiment of the present invention induces substantial plasma process environments, for example, etching environments, to be uniform over the entire wafer, such that process evenness over the entire wafer, for example, CD evenness, can be effectively implemented.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view illustrating a plasma chamber using a conventional plasma source coil;

FIG. 2 is a detailed illustration of the plasma source coil shown in FIG. 1;

FIG. 3 is a cross-sectional view illustrating a plasma chamber using a plasma source coil in accordance with a preferred embodiment of the present invention;

FIG. 4 is a detailed illustration of the plasma source coil shown in FIG. 3;

FIG. 5 shows a second example of the plasma source coil in accordance with a preferred embodiment of the present invention;

FIG. 6 shows a third example of the plasma source coil in accordance with a preferred embodiment of the present invention;

FIG. 7 shows a fourth example of the plasma source coil in accordance with a preferred embodiment of the present invention;

FIG. 8 is a cross-sectional view illustrating the plasma source coil shown in FIG. 7;

FIG. 9 shows a fifth example of the plasma source coil in accordance with a preferred embodiment of the present invention;

FIG. 10 is a cross-sectional view illustrating the plasma source coil shown in FIG. 9;

FIG. 11 shows a sixth example of the plasma source coil shown in accordance with a preferred embodiment of the present invention;

FIG. 12 is a cross-sectional view illustrating the plasma source coil shown in FIG. 11;

FIG. 13 shows a seventh example of the plasma source coil in accordance with a preferred embodiment of the present invention;

FIG. 14 shows an eighth example of the plasma source coil in accordance with a preferred embodiment of the present invention;

FIG. 15 shows a ninth example of the plasma source coil in accordance with a preferred embodiment of the present invention;

FIG. 16 shows a 10-th example of the plasma source coil in accordance with a preferred embodiment of the present invention;

FIG. 17 is a cross-sectional view illustrating the plasma source coils shown in FIGS. 13˜16;

FIG. 18 shows an 11-th example of the plasma source coil in accordance with a preferred embodiment of the present invention;

FIG. 19 shows a 12-th example of the plasma source coil in accordance with a preferred embodiment of the present invention;

FIG. 20 shows a 13-th example of the plasma source coil in accordance with a preferred embodiment of the present invention;

FIG. 21 shows a 14-th example of the plasma source coil in accordance with a preferred embodiment of the present invention;

FIG. 22 is a cross-sectional view illustrating a plasma chamber using a plasma source coil in accordance with another preferred embodiment of the present invention;

FIG. 23 is a plan view illustrating the plasma source coil shown in FIG. 22;

FIG. 24 shows an exemplary distance from the center part to individual edges of a wafer and a plasma source coil to illustrate a plasma source coil in accordance with another preferred embodiment of the present invention;

FIG. 25 shows exemplary distribution of a surface area from the center part of a plasma source coil to an edge of the plasma source coil in accordance with another preferred embodiment of the present invention;

FIG. 26 shows an exemplary unit coil contained in a plasma source coil in accordance with another preferred embodiment of the present invention;

FIG. 27 shows another exemplary distribution of a surface area from the center part of a plasma source coil to an edge of the plasma source coil in accordance with another preferred embodiment of the present invention;

FIG. 28 shows yet another exemplary distribution of a surface area from the center part of a plasma source coil to an edge of the plasma source coil in accordance with another preferred embodiment of the present invention;

FIG. 29 shows yet another exemplary distribution of a surface area from the center part of a plasma source coil to an edge of the plasma source coil in accordance with another preferred embodiment of the present invention;

FIG. 30 is a cross-sectional view illustrating a plasma chamber using a plasma source coil in accordance with yet another preferred embodiment of the present invention;

FIG. 31 is a plan view illustrating a plasma source coil in accordance with yet another preferred embodiment of the present invention;

FIG. 32 is a cross-sectional view illustrating the plasma source coil taken along the line A-A′ of FIG. 31;

FIG. 33 is a graph illustrating variation in distance between coils in the direction of a wafer edge of the plasma source coil shown in FIGS. 31˜32;

FIG. 34 is a graph illustrating a coil radius depending on a turning angle of the plasma source coil of FIGS. 31˜32;

FIG. 35 is a graph illustrating variation in the coil radius depending on the turning angle of the plasma source coil of FIGS. 31˜32; and

FIG. 36 is a graph illustrating CD distribution on a wafer due to the introduction of a plasma source coil in accordance with yet another preferred embodiment of the present invention.

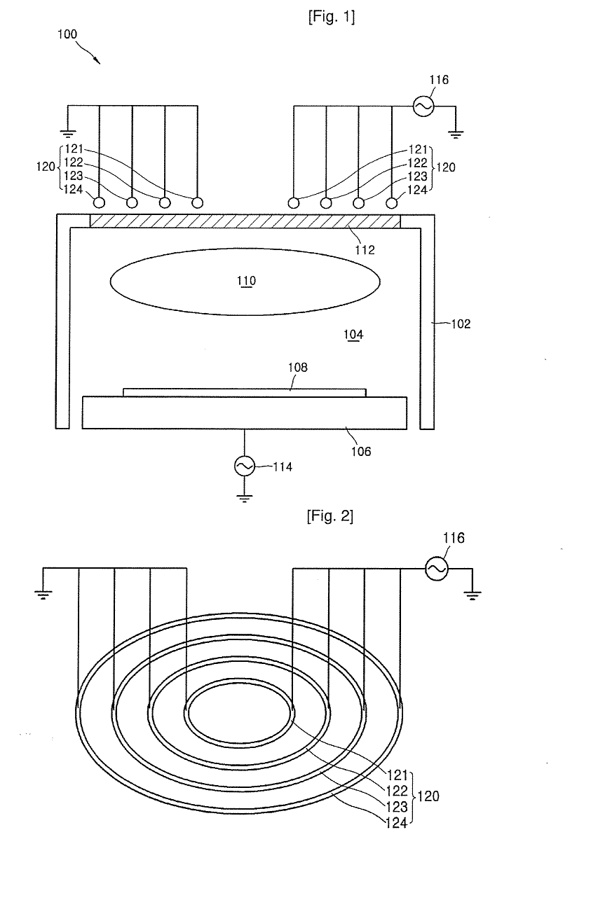

### BEST MODE FOR CARRYING OUT THE INVENTION

Now, preferred embodiments of the present invention will be described in detail with reference to the annexed drawings. In the drawings, the same or similar elements are denoted by the same reference numerals even though they are depicted in different drawings. In the following description, a detailed description of known functions and configurations incorporated herein will be omitted when it may make the subject matter of the present invention rather unclear.

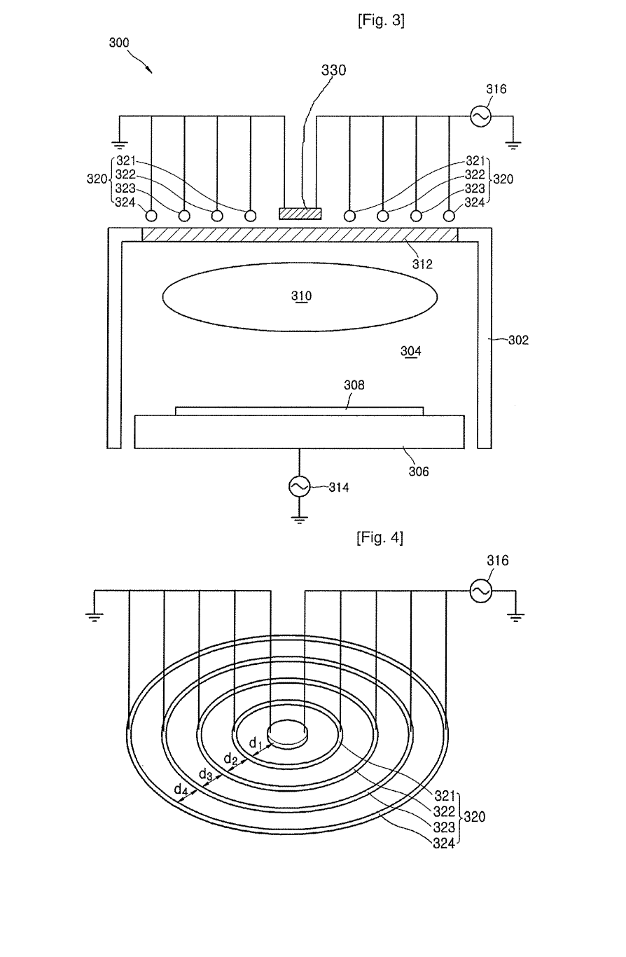

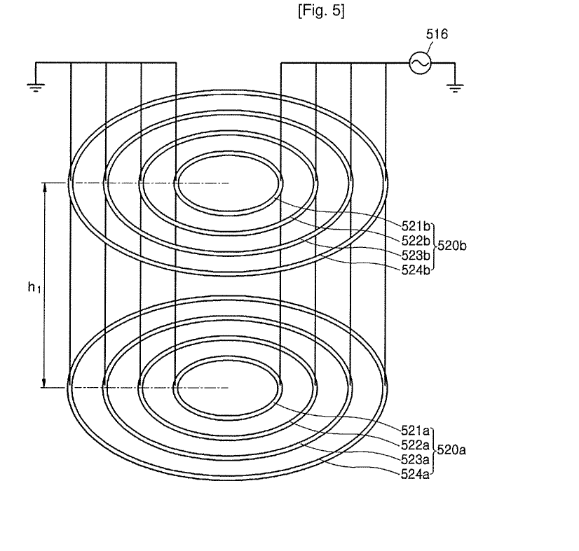

FIG. 3 is a cross-sectional view illustrating a plasma chamber using a plasma source coil in accordance with a preferred embodiment of the present invention. FIG. 4 is a detailed illustration of the plasma source coil shown in FIG. 3.

Referring to FIGS. 3˜4, the plasma chamber 300 in accordance with a preferred embodiment of the present invention includes a reaction space 304, which is defined by an exterior wall 302 and a dome 312. Plasma 310 is formed in a predetermined area of the reaction space 304 under predetermined conditions. Although the reaction space 304 is open at a lower part of the plasma chamber 300 as shown in FIG. 3, this illustration is provided only to simplify the drawings. Indeed, a lower part of the plasma chamber 300 is also isolated from an external part, such that a vacuum state can be maintained in the plasma chamber 300. A wafer support 306 is arranged at a lower part of the plasma chamber 300. A semiconductor wafer 308 to be processed is disposed on an upper surface of the wafer support 306. The wafer support 306 is connected to an external RF power-supply unit 314. The wafer support 306 may further include a heater therein (not shown in FIG. 3). The above-mentioned plasma chamber structure is applicable to all the plasma source coils depending on a variety of preferred embodiments to be explained later.

Plasma source coils 320 for forming plasma 310 are arranged at an exterior surface of the dome 312. As shown in FIG. 4, the plasma source coils 320 include a plurality of unit coils, i.e., first to fourth unit coils 321, 322, 323, and 324 connected in parallel, and a bushing 330. Although 4 unit coils are illustrated in the drawings, the number of unit coils may be freely selected as necessary. The bushing 330 is formed of a conductive material, and is configured in the form of a cylinder having a predetermined radius. However, the bushing 330 may take of other forms as necessary. The bushing 330 is disposed at the center part of the plasma chamber 300. The first unit coil 321 is spaced apart from the bushing 330 by a first distance “d1”, and at the same time encloses the bushing 330. The second unit coil 322 is spaced apart from the first unit coil 321 by a second distance “d2”, and at the same time encloses the first unit coil 321. The third unit coil 323 is spaced apart from the second unit coil 322 by a third distance “d3”, and at the same time encloses the second unit coil 322. The fourth unit coil 324 is spaced apart from the third unit coil 323 by a fourth distance “d4”, and at the same time encloses the third unit coil 323. The first distance “d1”, the second distance “d2”, the third distance “d3”, and the fourth distance “d4” may be equal to each other, or may be different from each other. If needed, some of the distances d1-d4 may be equal to each other, while the remaining distances are different from each other. Distribution of plasma contained in the plasma chamber 300 may be affected by spacing between unit coils, such that the etching rate, the selection ratio, and the CD, etc., are also affected. The first to fourth unit coils 321, 322, 323, and 324 and the bushing 330 are connected in parallel to the RF power-supply unit 316. The first to fourth unit coils 321, 322, 323, and 324 and the bushing 330 are also connected in parallel to a ground terminal.

According to the plasma source coil having the above-mentioned structure and the plasma chamber using the same, plasma density at the center part is lower than the other plasma density at the edge part due to the bushing 330 disposed at the center part, resulting in uniform distribution of

### ΔCD

. In more detail, more polymer-based by-products are generated at the center part due to relatively high plasma density at the center part. Since the etching rate is reduced due to the above-mentioned by-products, the

### ΔCD

distribution at the center part is different from the

### ΔCD

distribution at the edge part. The plasma density at the center part is reduced due to the presence of the bushing 330, and the amount of generated polymer-based by-products is also reduced, such that the

### ΔCD

distribution at the center part and the other

### ΔCD

distribution at the edge part are both uniform. Also, the unit coils and the bushing can be electrically connected in parallel, such that a power level of the RF power-supply unit 316 can be reduced.

FIG. 5 shows a second example of the plasma source coil in accordance with a preferred embodiment of the present invention.

Referring to FIG. 5, the plasma source coil according to the present invention includes a lower plasma source coil 520a and an upper plasma source coil 520b. The lower plasma source coil 520a is vertically spaced apart from the lower plasma source coil 520b by a predetermined distance “h1”, e.g., 0.5˜2.0 cm.

The lower plasma source coil 520a includes a plurality of lower unit coils 521a, 522a, 523a, and 524a. In more detail, the lower plasma source coil 520a includes a plurality of lower unit coils, e.g., the first, second, third, and fourth lower unit coils 521a, 522a, 523a, and 524a connected in parallel. In this case, although 4 lower unit coils are illustrated in FIG. 5, the number of lower unit coils may be freely selected as necessary. This configuration is also applied to other preferred embodiments. The first, second, third, and fourth lower unit coils 521a, 522a, 523a, and 524a are each configured in the form of a circle having a predetermined radius. If needed, the first to fourth lower unit coils 521a-524a may take of other forms as necessary. The first lower unit coil 521a is enclosed by the second lower unit coil 522a. The second lower unit coil 522a is enclosed by the third lower unit coil 523a. The third lower unit coil 523a is enclosed by the fourth unit coil 524a.

The lower plasma source coil 520b includes a plurality of upper unit coils 521b, 522b, 523b, and 524b. In more detail, the upper plasma source coil 520b includes a plurality of upper unit coils, e.g., the first, second, third, and fourth upper unit coils 521b, 522b, 523b, and 524b connected in parallel. The first, second, third, and fourth upper unit coils 521b, 522b, 523b, and 524b are arranged in the same manner as the first, second, third, and fourth lower unit coils 521a, 522a, 523a, and 524a.

The first, second, third, and fourth lower unit coils 521a, 522a, 523a, and 524a are connected in parallel to the RF power-supply unit 516. The first, second, third, and fourth lower unit coils 521a, 522a, 523a, and 524a are connected in parallel to a ground terminal. In this way, the first, second, third, and fourth upper unit coils 521b, 522b, 523b, and 524b are connected in parallel to the RF power-supply unit 516. The first, second, third, and fourth upper unit coils 521b, 522b, 523b, and 524b are connected in parallel to the ground terminal. The first lower unit coil 521a and the first upper unit coil 521b are connected to the RF power-supply unit 516 and the ground terminal via the same connection line. In this way, the second lower unit coil 522a and the second upper unit coil 522b are connected to the RF power-supply unit 516 and the ground terminal via the same connection line. The third lower unit coil 523a and the third upper unit coil 523b are connected to the RF power-supply unit 516 and the ground terminal via the same connection line. The fourth lower unit coil 524a and the fourth upper unit coil 524b are connected to the RF power-supply unit 516 and the ground terminal via the same connection line.

In the case of the plasma source coil denoted by 520a and 520b according to the present invention, a large number of unit coils are classified into lower and upper unit coils, and the lower and upper unit coils are arranged at lower and upper parts, respectively, such that spacing among unit coils can be equal to or higher than a predetermined value. In other words, the spacing among the unit coils in the case where the unit coils are differently arranged at the lower and upper parts can be relatively wider than that in the other case where the unit coils are all arranged at the same plane. In this way, spacing among unit coils is relatively wider, such that the plasma source coil according to the present invention can prevent an electric arc from being generated by narrow spacing among conventional unit coils.

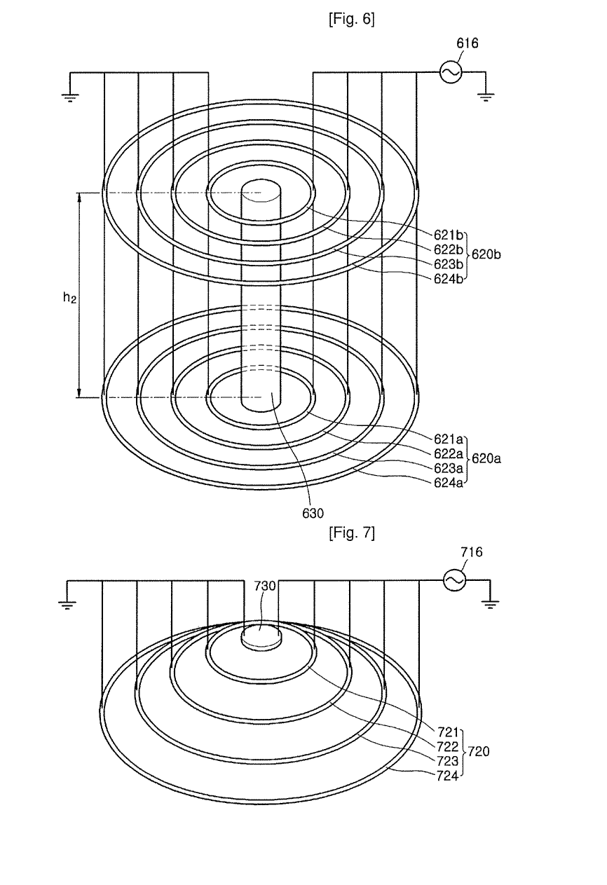

FIG. 6 shows a third example of the plasma source coil in accordance with a preferred embodiment of the present invention.

Referring to FIG. 6, the plasma source coil denoted by 620a, 620b, and 630 according to the present invention are similar to the above-mentioned plasma source coil denoted by 520a and 520b. The lower plasma source coil 620a is arranged at a lower part, and the upper plasma source coil 620b is arranged at an upper part. The lower plasma source coil 620a includes the first, second, third, and fourth lower unit coils 621a, 622a, 623a, and 624a. The upper plasma source coil 620b includes the first, second, third, and fourth upper unit coils 621b, 622b, 623b, and 624b. However, the plasma source coil shown in FIG. 6 according to the present invention includes the bushing 630 at its center part, differently from the plasma source coil denoted by 520a and 520b shown in FIG. 5. The bushing 630 is configured in the form of a cylinder by which the center part of the lower plasma source coil 620a is connected to the center part of the upper plasma source coil 620b. The lower plasma source coil 620a is disposed on a plane where the bottom of the bushing 630 is also disposed. The upper plasma source coil 620b is disposed on a plane where the top of the bushing 630 is also disposed. The bushing 630 reduces plasma density at the center part, such that less polymer-based by-products occur in the center part, resulting in uniform distribution of

### ΔCD

at the center and edge parts. Also, in the case of the plasma source coil denoted by 620a, 620b, and 630 according to the present invention, individual distances among the first, second, third, and fourth lower unit coils 621a, 622a, 623a, and 624a contained in the lower plasma source coil 620a may be equal to each other, or may also be different from each other. If needed, some of the distances may be equal to each other, while the remaining distances are different from each other. In this way, individual distances among the first, second, third, and fourth upper unit coils 621b, 622b, 623b, and 624b contained in the upper plasma source coil 620b may be equal to each other, and may also be different from each other. If needed, some of the distances may be equal to each other, while the remaining distances are different from each other.

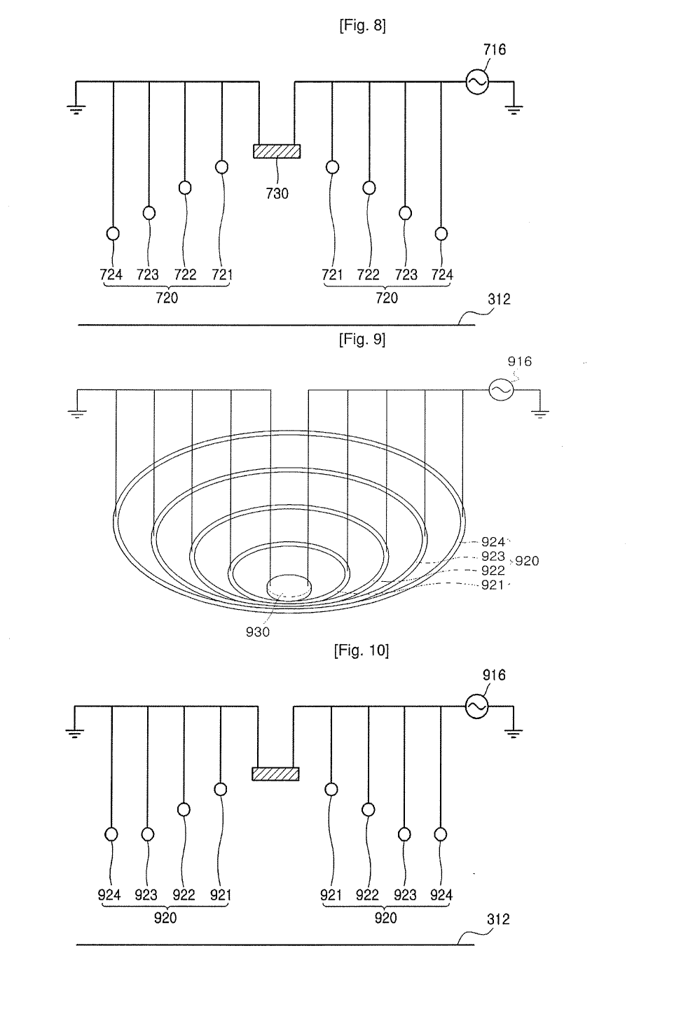

FIG. 7 shows a fourth example of the plasma source coil in accordance with a preferred embodiment of the present invention. FIG. 8 is a cross-sectional view illustrating the plasma source coil shown in FIG. 7.

Referring to FIGS. 7 and 8, the plasma source coil denoted by 720 and 730 according to the present invention is the same as the plasma source coil denoted by 320 and 330 shown in FIG. 4. However, a plurality of unit coils 720, i.e., first, second, third, and fourth unit coils 721, 722, 723, and 724 are not disposed on the same plane, and are arranged on a convex shape, such that the first to fourth unit coils 721˜724 are arranged on a convex shape whose center part is more convex than an edge thereof, differently from the plasma source coil shown in FIG. 4. In other words, the first, second, third, and fourth unit coils 721, 722, 723, and 724 are sequentially disposed in the vicinity of the bushing 730 positioned at the center part. Distances among individual unit coils 720 may be equal to each other, or may be different from each other. If needed, some of the distances may be equal to each other, while the remaining distances are different from each other. The bushing 730 and the first to fourth unit coils 721, 722, 723, and 724 are connected in parallel to an RF power-supply unit 716. The bushing 730 and the first to fourth unit coils 721, 722, 723, and 724 are also connected in parallel to a ground terminal.

The bushing 730 is maximally spaced apart from the top surface of a dome 312. In the order of the first unit coil 721->the second unit coil 722->the third unit coil 723->the fourth unit coil 724, namely, the closer the coil position is to the edge of the plasma source coil, the less the distance from the dome 312. In this way, the closer the coil position is to the center part, the longer the distance from the dome 312. As a result, the closer the coil position is to the center part, the lower the plasma density.

FIG. 9 shows a fifth example of the plasma source coil in accordance with a preferred embodiment of the present invention. FIG. 10 is a cross-sectional view illustrating the plasma source coil shown in FIG. 9.

Referring to FIGS. 9 and 10, the plasma source coil denoted by 920 and 930 according to the present invention is the same as the plasma source coil denoted by 320 and 330 shown in FIG. 4. However, a plurality of unit coils 920, i.e., first, second, third, and fourth unit coils 921, 922, 923, and 924 are not disposed on the same plane, and are arranged on a convex shape, such that the first to fourth unit coils 921˜924 are arranged on a convex shape whose center part is more convex than an edge thereof, differently from the plasma source coil shown in FIG. 4. In other words, the first, second, third, and fourth unit coils 921, 922, 923, and 924 are sequentially disposed in the vicinity of the bushing 930 positioned at the center part. Distances among individual unit coils 920 may be equal to each other, or may be different from each other. If needed, some of the distances may be equal to each other, while the remaining distances are different from each other. The bushing 930 and the first to fourth unit coils 921, 922, 923, and 924 are connected in parallel to an RF power-supply unit 916. The bushing 930 and the first to fourth unit coils 921, 922, 923, and 924 are also connected in parallel to a ground terminal.

The bushing 930 is minimally spaced apart from the top surface of the dome 312. In the order of the first unit coil 921->the second unit coil 922->the third unit coil 923->the fourth unit coil 924, namely, the closer the coil position is to the edge part, the longer the distance from the dome 312. In the case of the plasma source coil denoted by 920 and 930 according to the present invention, the closer the coil position is to the center part, the longer the distance from the dome 312. Therefore, the closer the coil position is to the center part, the higher the plasma density. In this case, etching gas having a high ratio of fluorine (F) to carbon (c), i.e., a high F/C ratio, is used. The etching gas of a high F/C ratio generates less polymers acting as by-products. For example, the above-mentioned etching gas is indicative of CF₄, C₂F₆, C₃F₈, or CHF₃, etc. In this case, the etching gas, such as CF₄, C₂F₆, C₃F₈, or CHF₃, generally has an F/C ratio greater than “2”. In this case, over etching occurs at the edge of a wafer as compared to the center part of the wafer, resulting in uneven distribution of

### ΔCD

. The plasma source coil 920 according to the present invention reduces plasma density at the edge of the wafer, resulting in uniform distribution of

### ΔCD

.

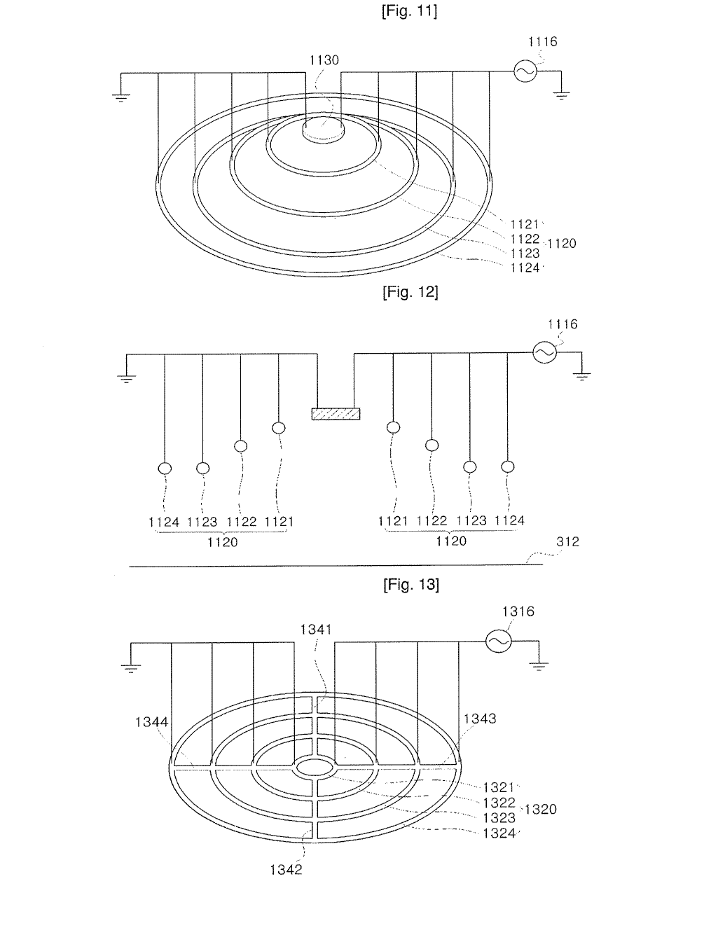

FIG. 11 shows a sixth example of the plasma source coil shown in accordance with a preferred embodiment of the present invention. FIG. 12 is a cross-sectional view illustrating the plasma source coil shown in FIG. 11.

Referring to FIGS. 11 and 12, the plasma source coil denoted by 1120 and 1130 according to the present invention is the same as the plasma source coil denoted by 720 and 730 shown in FIGS. 7 and 8. In other words, the first, second, third, and fourth unit coils 1121, 1122, 1123, and 1124 are sequentially disposed in the vicinity of the bushing 1130 positioned at the center part. Distances among individual unit coils 1120 may be equal to each other, or may be different from each other. If needed, some of the distances may be equal to each other, while the remaining distances are different from each other. The bushing 1130 and the first to fourth unit coils 1121, 1122, 1123, and 1124 are connected in parallel to an RF power-supply unit 1116. The bushing 1130 and the first to fourth unit coils 1121, 1122, 1123, and 1124 are also connected in parallel to a ground terminal. However, the plasma source coil denoted by 1120 and 1130 shown in FIGS. 11˜12 according to the present invention is configured in the form of a convex shape, and the third and fourth unit coils 1123 and 1124 disposed at the outermost location of the plasma source coil are disposed on the same plane, differently from the above-mentioned plasma source coils according to a variety of preferred embodiments having been previously disclosed. The plasma source coil denoted by 1120 and 1130 is adapted to maintain predetermined plasma density at the edge part.

FIG. 13 shows a seventh example of the plasma source coil in accordance with a preferred embodiment of the present invention.

Referring to FIG. 13, the plasma source coil according to the present invention includes a plurality of unit coils 1320, for example, first, second, third, and fourth unit coils 1321, 1322, 1323, and 1324. The first unit coil 1321 is arranged at the center part. The second unit coil 1322 is spaced apart from the first unit coil 1321 by a predetermined distance, and encloses the first unit coil 1321. The third unit coil 1323 is spaced apart from the second unit coil 1322 by a predetermined distance, and encloses the second unit coil 1322. The fourth unit coil 1324 is spaced apart from the third unit coil 1323 by a predetermined distance, and encloses the third unit coil 1323. Distances among the unit coils 1320 may be equal to each other, or may also be different from each other. If needed, some of the distances may be equal to each other, while the remaining distances are different from each other. The first, second, third, and fourth unit coils 1321, 1322, 1323, and 1324 are connected in parallel to an RF power-supply unit 1316. The first, second, third, and fourth unit coils 1321, 1322, 1323, and 1324 are also connected to a ground terminal.

The first, second, third, and fourth unit coils 1321, 1322, 1323, and 1324 are electrically connected to each other via a first connection line 1341, a second connection line 1342, a third connection line 1343, and a fourth connection line 1344. The first connection line 1341, the second connection line 1342, the third connection line 1343, and the fourth connection line 1344 are arranged perpendicular to each other. Particularly, the first connection line 1341 and the second connection line 1342 are vertically arranged, and the third connection line 1343 and the fourth connection line 1344 are horizontally arranged.

The above-mentioned plasma source coil can disperse the path of a current signal received from the RF power-supply unit 1316 in various ways. In more detail, a current signal applied to the first unit coil 1321 is divided into three sub-current signals, which flow through the second, third, and fourth unit coils 1322, 1323, and 1324 via the first, second, third, and fourth connection lines 1341, 1342, 1343, and 1344, before flowing to a ground terminal. The current flowing through various paths affects the electric field distribution, and induces variation in the electric field distribution, such that it can also induce the plasma density distribution.

FIG. 14 shows an eighth example of the plasma source coil in accordance with a preferred embodiment of the present invention.

Referring to FIG. 14, the plasma source coil according to the present invention includes a plurality of unit coils 1420, for example, first, second, third, and fourth unit coils 1421, 1422, 1423, and 1424. The first, second, third, and fourth unit coils 1421, 1422, 1423, and 1424 are arranged in the same manner as in FIG. 13, as such, a detailed description thereof will herein be omitted for the convenience of description. The first, second, third, and fourth unit coils 1421, 1422, 1423, and 1424 are connected to an RF power-supply unit 1416, and are connected to a ground terminal. The first unit coil 1421 and the second unit coil 1422 are electrically connected to each other via first connection lines 1441, 1442, 1443, and 1444. The second unit coil 1422 and the third unit coil 1423 are electrically connected to each other via second connection lines 1451, 1452, 1453, and 1454. The third unit coil 1423 and the fourth unit coil 1424 are electrically connected to each other via third connection lines 1461, 1462, 1463, and 1464. The first connection lines 1441˜1444, the second connection lines 1451˜1454, and the third connection lines 1461˜1464 are not directly connected to each other, and are alternately arranged.

The above-mentioned plasma source coil can disperse the path of a current received from the RF power-supply unit 1416 in various ways. In more detail, a current signal applied to the first unit coil 1421 is partially applied to the second unit coil 1422 via first connection lines 1441, 1442, 1443, and 1444. A current signal applied to the second unit coil 1422 is partially applied to the third unit coil 1423 via second connection lines 1451, 1452, 1453, and 1454. A current signal applied to the third unit coil 1423 is partially applied to the fourth unit coil 1424 via third connection lines 1461, 1462, 1463, and 1464. The above-mentioned operations are also applied to the other case opposite to the above-mentioned case. For example, a current signal applied to the fourth unit coil 1424 is partially applied to the third unit coil 1423 via third connection lines 1461, 1462, 1463, and 1464. The current signal flowing through various paths affects the electric field distribution, and induces variation in the electric field distribution, such that it can also induce the distribution of overall plasma density.

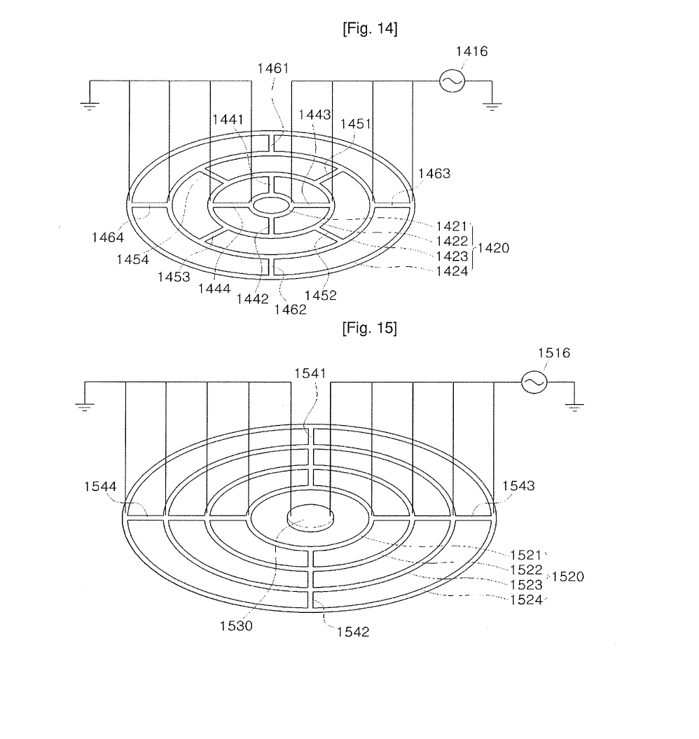

FIG. 15 shows a ninth example of the plasma source coil in accordance with a preferred embodiment of the present invention.

Referring to FIG. 15, the plasma source coil according to the present invention includes a bushing 1530 disposed at the center part thereof, and a plurality of unit coils 1520 in the vicinity of the bushing 1530, for example, first, second, third, and fourth unit coils 1521, 1522, 1523, and 1524. The first unit coil 1521 is spaced apart from the bushing 1530 by a predetermined distance, and encloses the bushing 1530. The second unit coil 1522 is spaced apart from the first unit coil 1521 by a predetermined distance, and encloses the first unit coil 1521. The third unit coil 1523 is spaced apart from the second unit coil 1522 by a predetermined distance, and encloses the second unit coil 1522. The fourth unit coil 1524 is spaced apart from the third unit coil 1523 by a predetermined distance, and encloses the third unit coil 1523. Distances among the unit coils 1520 may be equal to each other, or may also be different from each other. If needed, some of the distances may be equal to each other, while the remaining distances are different from each other. The first, second, third, and fourth unit coils 1521, 1522, 1523, and 1524 and the bushing 1530 are connected to an RF power-supply unit 1516. The first, second, third, and fourth unit coils 1521, 1522, 1523, and 1524 are also connected to a ground terminal. The first, second, third, and fourth unit coils 1521, 1522, 1523, and 1524 are electrically connected to each other via a first connection line 1541, a second connection line 1542, a third connection line 1543, and a fourth connection line 1544. The first connection line 1541, the second connection line 1542, the third connection line 1543, and the fourth connection line 1544 are arranged perpendicular to each other. Particularly, the first connection line 1541 and the second connection line 1542 are vertically arranged, and the third connection line 1543 and the fourth connection line 1544 are horizontally arranged.

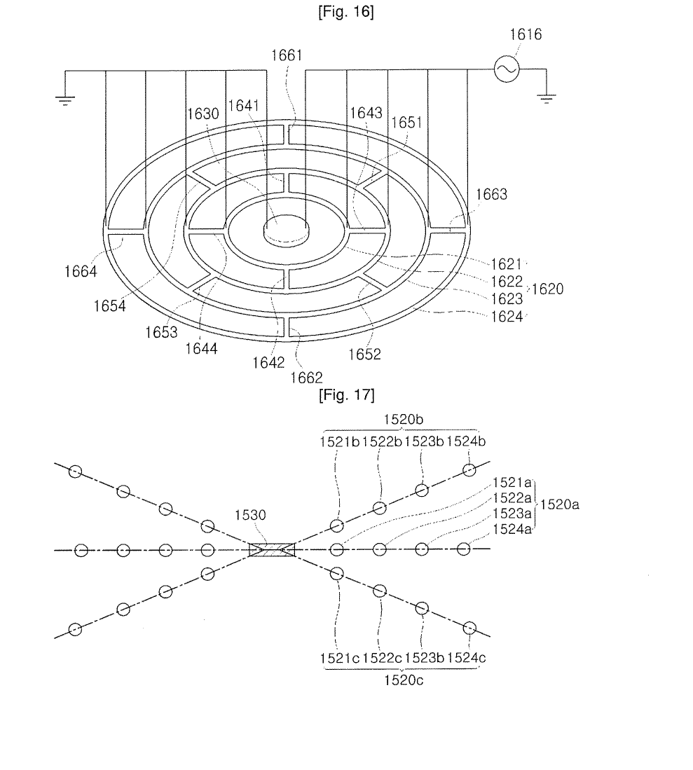

FIG. 16 shows a 10-th example of the plasma source coil in accordance with a preferred embodiment of the present invention.

Referring to FIG. 16, the plasma source coil according to the present invention includes a bushing 1630 disposed at the center part thereof, and a plurality of unit coils 1620 in the vicinity of the bushing 1630, for example, first, second, third, and fourth unit coils 1621, 1622, 1623, and 1624. The first, second, third, and fourth unit coils 1621, 1622, 1623, and 1624 are arranged in the same manner as in FIG. 15, as such, a detailed description thereof will herein be omitted for the convenience of description. The first, second, third, and fourth unit coils 1621, 1622, 1623, and 1624 and the bushing 630 are connected to an RF power-supply unit 1616, and are also connected to a ground terminal. The first unit coil 1621 and the second unit coil 1622 are electrically connected to each other via first connection lines 1641, 1642, 1643, and 1644. The second unit coil 1622 and the third unit coil 1623 are electrically connected to each other via second connection lines 1651, 1652, 1653, and 1654. The third unit coil 1623 and the fourth unit coil 1624 are electrically connected to each other via third connection lines 1661, 1662, 1663, and 1664. The first connection lines 1641-1644, the second connection lines 1651-1654, and the third connection lines 1661-1664 are not directly connected to each other, and are alternately arranged.

FIG. 17 is a cross-sectional view illustrating the plasma source coils shown in FIGS. 13˜16. Although the following description uses the above-mentioned plasma source coil shown in FIG. 15 for the purpose of illustration, it should be noted that this configuration can also be applied to plasma source coils shown in FIGS. 13, 14, and 16.

Referring to FIG. 17, a plurality of unit coils are arranged along a circumference of a bushing 1530 disposed at the center part of the plasma source coil, and the following first to third structures can be selectively included in FIG. 17. The first structure includes unit coils 1520a arranged on the same plane in the range from the bushing 1530 to the edge part. The second structure arranges unit coils 1520b on a concave shape, such that the closer the coil position is to the edge part on the basis of the bushing 530, the longer the distance from a dome (not shown). The third structure arranges unit coils 1520c on a convex shape, such that the closer the coil position is to the edge part on the basis of the bushing 1530, the shorter the distance from the dome. In more detail, in the case of the first unit coils 1520a, the first, second, third, and fourth unit coils 1521a, 1522a, 1523a, and 1524a are disposed on the same plane, such that distances between the first to fourth unit coils 1521a˜1524a and the dome are maintained constant. In the case of the second unit coils 1520b, a distance between each of unit coils 1521b-1524b and the dome increases in the order of the first unit coil 1521b->the second unit coil 1522b->the third unit coil 1523b->the fourth unit coil 1524b. In the case of the third unit coils 1520c, a distance between each of unit coils 1521c˜1524c and the dome decreases in the order of the first unit coil 1521c->the second unit coil 1522c->the third unit coil 1523c->the fourth unit coil 1524c.

If the same arrangement as in the unit coils 1520a contained in the above-mentioned first structure is provided, a difference between plasma density at the center part and the other plasma density at the edge part is relatively lower than in the unit coils 1520b contained in the second structure or in the unit coils 1520c contained in the third structure. In the case of the unit coils 1520b contained in the second structure, the closer the coil position is to the edge part, the lower the plasma density. In the case of the unit coils 1520c contained in the third structure, the closer the coil position is to the center part, the higher the plasma density.

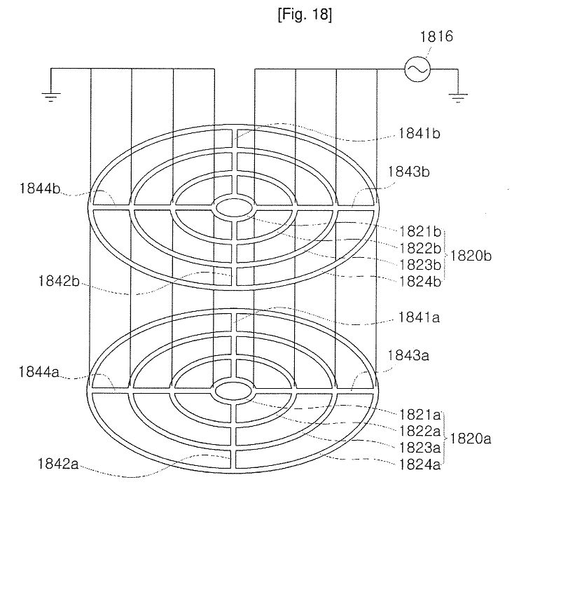

FIG. 18 shows an 11-th example of the plasma source coil in accordance with a preferred embodiment of the present invention.

Referring to FIG. 18, the plasma source coil according to the present invention includes a lower plasma source coil 1820a and an upper plasma source coil 1820b. The lower plasma source coil 1820a and the upper plasma source coil 1820b are vertically spaced apart from each other by a predetermined distance.

The lower plasma source coil 1820a includes lower unit coils 1821a, 1822a, 1823a, and 1824a. In more detail, the lower plasma source coil 1820a includes a plurality of lower unit coils, for example, first to fourth lower unit coils 1821a, 1822a, 1823a, and 1824a. Although 4 lower unit coils are illustrated in FIG. 18, the number of lower unit coils may be freely selected as necessary. First to fourth unit coils 1821a, 1822a, 1823a, and 1824a are each configured in the form of a circle having a predetermined radius. The first lower unit coil 1821a is enclosed by the second lower unit coil 1822a, the second lower unit coil 1822a is enclosed by the third lower unit coil 1823a, and the third lower unit coil 1823a is enclosed by the fourth lower unit coil 1824a.

The first, second, third, and fourth unit coils 1821a, 1822a, 1823a, and 1824a are electrically connected to each other via a first lower connection line 1841a, a second lower connection line 1842a, a third lower connection line 1843a, and a fourth lower connection line 1844a. The first lower connection line 1841a, the second lower connection line 1842a, the third lower connection line 1843a, and the fourth lower connection line 1844a are arranged perpendicular to each other. Particularly, the first lower connection line 1841a and the second lower connection line 1842a are arranged in a first direction, and the third lower connection line 1843a and the fourth lower connection line 1844a are arranged in a second direction perpendicular to the first direction.

The upper plasma source coil 1820b includes a plurality of upper unit coils 1821b, 1822b, 1823b, and 1824b. In more detail, the upper plasma source coil 1820b includes four upper unit coils, i.e., first, second, third, and fourth unit coils 1821b, 1822b, 1823b, and 1824b. Although 4 upper unit coils are illustrated in FIG. 18, the number of upper unit coils may be freely selected as necessary. First to fourth unit coils 1821b, 1822b, 1823b, and 1824b are each configured in the form of a circle having a predetermined radius. The first lower unit coil 1821b is enclosed by the second upper unit coil 1822b, the second lower unit coil 1822b is enclosed by the third lower unit coil 1823b, and the third lower unit coil 1823b is enclosed by the fourth lower unit coil 1824b.

The first, second, third, and fourth upper unit coils 1821b, 1822b, 1823b, and 1824b are electrically connected to each other via a first upper connection line 1841b, a second upper connection line 1842b, a third upper connection line 1843b, and a fourth upper connection line 1844b. The first upper connection line 1841b, the second upper connection line 1842b, the third upper connection line 1843b, and the fourth upper connection line 1844b are arranged perpendicular to each other. Particularly, the first upper connection line 1841b and the second upper connection line 1842b are arranged in a first direction, and the third upper connection line 1843b and the fourth lower connection line 1844b are arranged in a second direction perpendicular to the first direction.

Although there is no illustration in FIG. 18, it should be noted that the first lower connection line 1841a and the first upper connection line 1841b may be directly connected to each other via a first connection line (not shown) arranged in a vertical direction. The second lower connection line 1842a and the second upper connection line 1842b are also directly connected to each other via a second connection line (not shown) arranged in a vertical direction. In this way, the third lower connection line 1843a and the third upper connection line 1843b may be directly connected to each other, and the fourth lower connection line 1844a and the fourth upper connection line 1844b may also be directly connected to each other.

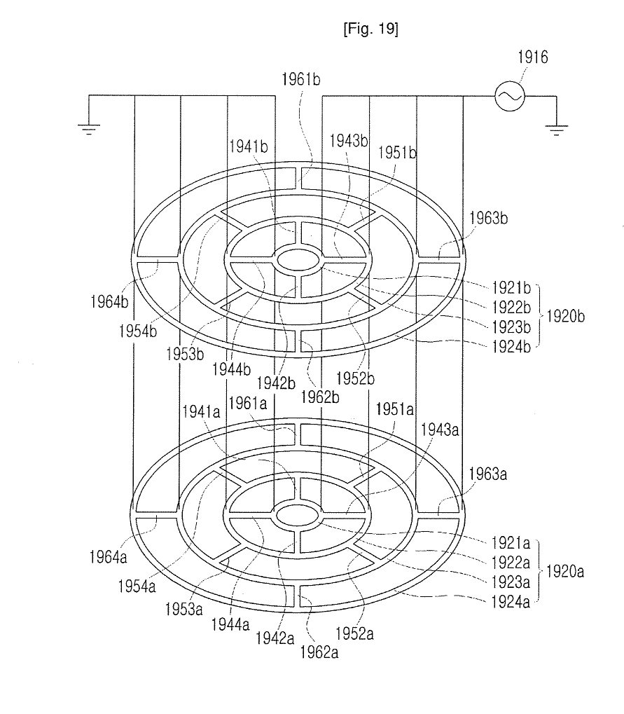

FIG. 19 shows a 12-th example of the plasma source coil in accordance with a preferred embodiment of the present invention.

Referring to FIG. 19, the plasma source coil according to the present invention includes a lower plasma source coil 1920a and an upper plasma source coil 1920b. The lower plasma source coil 1920a and the upper plasma source coil 1920b are vertically spaced apart from each other by a predetermined distance.

The lower plasma source coil 1920a includes a plurality of lower unit coils 1921a, 1922a, 1923a, and 1924a. In more detail, the lower plasma source coil 1920a includes a plurality of lower unit coils, e.g., first, second, third, and fourth lower unit coils 1921a, 1922a, 1923a, and 1924a. Although 4 lower unit coils are illustrated in FIG. 19, the number of lower unit coils may be freely selected as necessary. The first, second, third, and fourth lower unit coils 1921a, 1922a, 1923a, and 1924a are arranged in the same manner as in FIG. 18, as such, a detailed description thereof will herein be omitted for the convenience of description.

The first, second, third, and fourth lower unit coils 1921a, 1922a, 1923a, and 1924a are connected to an RF power-supply unit 1916, and are also connected to a ground terminal. The first lower unit coil 1921a and the second lower unit coil 1922a are electrically connected to each other via first lower connection lines 1941a, 1942a, 1943a, and 1944a. The second lower unit coil 1922a and the third lower unit coil 1923a are electrically connected to each other via second lower connection lines 1951a, 1952a, 1953a, and 1954a. The third lower unit coil 1923a and the fourth lower unit coil 1924a are electrically connected to each other via third lower connection lines 1961a, 1962a, 1963a, and 1964a. The first lower connection lines 1941a˜1944a, the second lower connection lines 1951a˜1954a, and the third lower connection lines 1961a˜1964a are not directly connected to each other, and are alternately arranged.

The upper plasma source coil 1920b includes a plurality of upper unit coils 1921b, 1922b, 1923b, and 1924b. In more detail, the upper plasma source coil 1920b includes a plurality of upper unit coils, e.g., first, second, third, and fourth upper unit coils 1921b, 1922b, 1923b, and 1924b. Although 4 upper unit coils are illustrated in FIG. 19, the number of upper unit coils may be freely selected as necessary. The first, second, third, and fourth upper unit coils 1921b, 1922b, 1923b, and 1924b are arranged in the same manner as in FIG. 18, as such, a detailed description thereof will herein be omitted for the convenience of description.

The first, second, third, and fourth upper unit coils 1921b, 1922b, 1923b, and 1924b are connected to an RF power-supply unit 1916, and are also connected to a ground terminal. The first upper unit coil 1921b and the second upper unit coil 1922b are electrically connected to each other via first upper connection lines 1941b, 1942b, 1943b, and 1944b. The second upper unit coil 1922b and the third upper unit coil 1923b are electrically connected to each other via second upper connection lines 1951b, 1952b, 1953b, and 1954b. The third upper unit coil 1923b and the fourth upper unit coil 1924b are electrically connected to each other via third upper connection lines 1961b, 1962b, 1963b, and 1964b. The first upper connection lines 1941b-1944b, the second upper connection lines 1951b˜1954b, and the third upper connection lines 1961b˜1964b are not directly connected to each other, and are alternately arranged.

Although there is no illustration in FIG. 19, it should be noted that the second lower connection line 1951a and the second upper connection line 1951b may be directly connected to each other via a first connection line (not shown) arranged in a vertical direction. The third lower connection line 1962a and the third upper connection line 1962b are also directly connected to each other via a second connection line (not shown) arranged in a vertical direction. In this way, one of the first lower connection lines 1941a, 1942a, 1943a, and 1944a may be directly connected to one of the first upper connection lines 1941b, 1942b, 1943b, and 1944b. Also, other lower connection lines may also be directly connected to other upper connection lines.

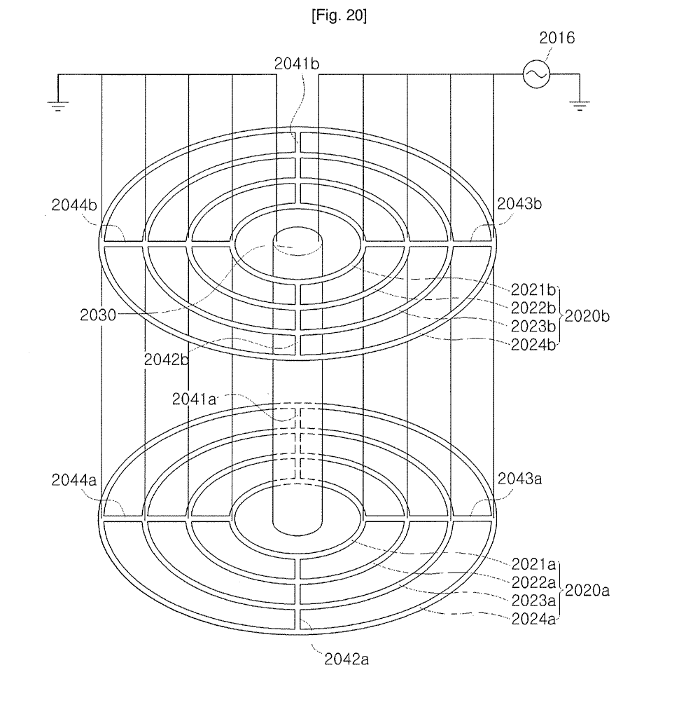

FIG. 20 shows a 13-th example of the plasma source coil in accordance with a preferred embodiment of the present invention.

Referring to FIG. 20, the plasma source coil according to the present invention includes a cylindrical bushing 2030 vertically arranged at the center part thereof, a lower plasma source coil 2020a disposed on a plane where the bottom of a bushing 2030 is also disposed, and an upper plasma source coil 2020b disposed on a plane where the top of the bushing 2030 is also disposed. The lower plasma source coil 2020a and the upper plasma source coil 2020b are vertically spaced apart from each other by a predetermined distance corresponding to the length of the bushing 2030.

The lower plasma source coil 2020a includes a plurality of lower unit coils 2021a, 2022a, 2023a, and 2024a. In more detail, the lower plasma source coil 2020a includes a plurality of lower unit coils arranged along a circumference of the bushing 2030, for example, first, second, third, and fourth lower unit coils 2021a, 2022a, 2023a, and 2024a. Although 4 lower unit coils are illustrated in FIG. 20, the number of lower unit coils may be freely selected as necessary. First to fourth lower unit coils 2021a, 2022a, 2023a, and 2024a are each configured in the form of a circle having a predetermined radius.

The first, second, third, and fourth lower unit coils 2021a, 2022a, 2023a, and 2024a are electrically connected to each other via a first lower connection line 2041a, a second lower connection line 2042a, a third lower connection line 2043a, and a fourth lower connection line 2044a. The first lower connection line 2041a, the second lower connection line 2042a, the third lower connection line 2043a, and the fourth lower connection line 2044a are arranged perpendicular to each other. For example, the first lower connection line 2041a and the second lower connection line 2042a are arranged in a first direction, and the third lower connection line 2043a and the fourth lower connection line 2044a are arranged in a second direction perpendicular to the first direction.

The upper plasma source coil 2020b includes a plurality of upper unit coils 2021b, 2022b, 2023b, and 2024b. In more detail, the upper plasma source coil 2020b includes a plurality of upper unit coils arranged along a circumference of the bushing 2030, for example, first, second, third, and fourth upper unit coils 2021b, 2022b, 2023b, and 2024b. Although 4 upper unit coils are illustrated in FIG. 20, the number of upper unit coils may be freely selected as necessary. First to fourth upper unit coils 2021b, 2022b, 2023b, and 2024b are each configured in the form of a circle having a predetermined radius.

The first, second, third, and fourth upper unit coils 2021b, 2022b, 2023b, and 2024b are electrically connected to each other via a first upper connection line 2041b, a second upper connection line 2042b, a third upper connection line 2043b, and a fourth upper connection line 2044b. The first upper connection line 2041b, the second upper connection line 2042b, the third upper connection line 2043b, and the fourth upper connection line 2044b are arranged perpendicular to each other. For example, the first upper connection line 2041b and the second upper connection line 2042b are arranged in a first direction, and the third upper connection line 2043b and the fourth upper connection line 2044b are arranged in a second direction perpendicular to the first direction.

Although there is no illustration in FIG. 20, it should be noted that the first lower connection line 2041a and the first upper connection line 2041b may be directly connected to each other via a first connection line (not shown) arranged in a vertical direction. The second lower connection line 2042a and the second upper connection line 2042b are also directly connected to each other via a second connection line (not shown) arranged in a vertical direction. In this way, the third lower connection line 2043a and the third upper connection line 2043b may be directly connected to each other, and the fourth lower connection line 2044a and the fourth upper connection line 2044b may also be directly connected to each other.

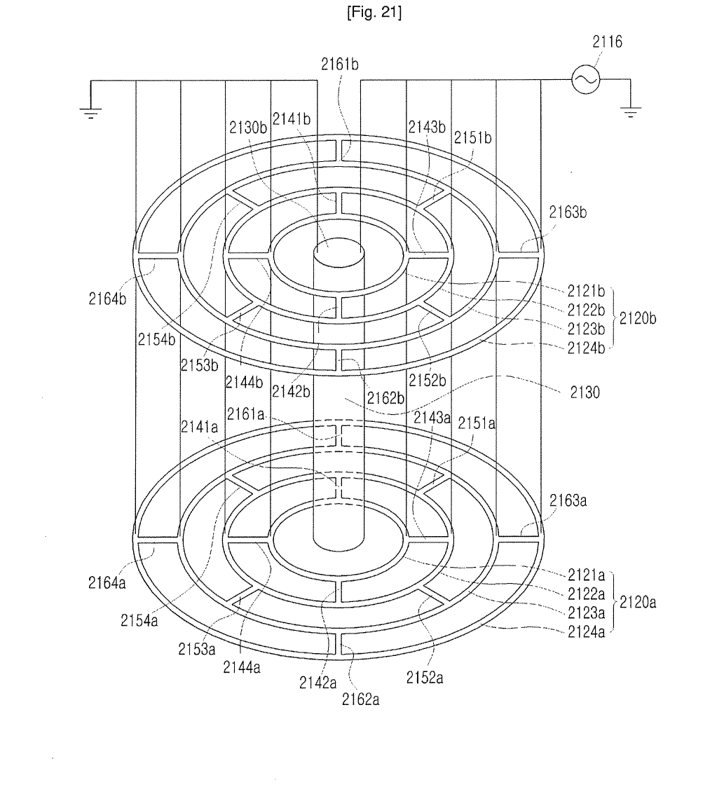

FIG. 21 shows a 14-th example of the plasma source coil in accordance with a preferred embodiment of the present invention.

Referring to FIG. 21, the plasma source coil according to the present invention includes a cylindrical bushing 2130 vertically arranged at the center part, a lower plasma source coil 2120a disposed on a plane where the bottom of a bushing 2130 is also disposed, and an upper plasma source coil 2120b disposed on a plane where the top of the bushing 2130 is also disposed. The lower plasma source coil 2120a and the upper plasma source coil 2120b are vertically spaced apart from each other by a predetermined distance corresponding to the length of the bushing 2130.

The lower plasma source coil 2120a includes a plurality of lower unit coils 2121a, 2122a, 2123a, and 2124a. In more detail, the lower plasma source coil 2120a includes a plurality of lower unit coils, for example, first, second, third, and fourth lower unit coils 2121a, 2122a, 2123a, and 2124a. Although 4 unit coils are illustrated in FIG. 21, the number of unit coils may be freely selected as necessary. The first, second, third, and fourth lower unit coils 2121a, 2122a, 2123a, and 2124a are arranged in the same manner as in FIG. 20, as such, a detailed description thereof will herein be omitted for the convenience of description.

The first, second, third, and fourth lower unit coils 2121a, 2122a, 2123a, and 2124a are connected to an RF power-supply unit 2116, and are also connected to a ground terminal. The first lower unit coil 2121a and the second lower unit coil 2122a are electrically connected to each other via first lower connection lines 2141b, 2142b, 2143b, and 2144b. The second lower unit coil 2122a and the third lower unit coil 2123a are electrically connected to each other via second lower connection lines 2151a, 2152a, 2153a, and 2154a. The third lower unit coil 2123b and the fourth lower unit coil 2124a are electrically connected to each other via third lower connection lines 2161a, 2162a, 2163a, and 2164a. The first lower connection lines 2141a˜2144a, the second lower connection lines 2151b˜2154b, and the third lower connection lines 2161a˜2164a are not directly connected to each other, and are alternately arranged.

The upper plasma source coil 2120b includes a plurality of upper unit coils 2121b, 2122b, 2123b, and 2124b. In more detail, the upper plasma source coil 2120b includes a plurality of upper unit coils arranged along a circumference of the bushing 2030, for example, first, second, third, and fourth upper unit coils 2121b, 2122b, 2123b, and 2124b. Although 4 unit coils are illustrated in FIG. 21, the number of unit coils may be freely selected as necessary. The first, second, third, and fourth upper unit coils 2121b, 2122b, 2123b, and 2124b are arranged in the same manner as in FIG. 20, as such, a detailed description thereof will herein be omitted for the convenience of description.

The first, second, third, and fourth upper unit coils 2121b, 2122b, 2123b, and 2124b are connected to the RF power-supply unit 2116, and are also connected to the ground terminal. The first upper unit coil 2121b and the second upper unit coil 2122b are electrically connected to each other via first upper connection lines 2141b, 2142b, 2143b, and 2144b. The second upper unit coil 2122b and the third upper unit coil 2123b are electrically connected to each other via second upper connection lines 2151b, 2152b, 2153b, and 2154b. The third upper unit coil 2123b and the fourth upper unit coil 2124b are electrically connected to each other via third upper connection lines 2161b, 2162b, 2163b, and 2164b. The first upper connection lines 2141b-2144b, the second upper connection lines 2151b-2154b, and the third upper connection lines 2161b˜2164b are not directly connected to each other, and are alternately arranged.

Although there is no illustration in FIG. 21, it should be noted that the second lower connection line 2151a and the second upper connection line 2151b may be directly connected to each other via a first connection line (not shown) arranged in a vertical direction. The third lower connection line 2162a and the third upper connection line 2162b are also directly connected to each other via a second connection line (not shown) arranged in a vertical direction. In this way, one of the first lower connection lines 2141a, 2142a, 2143a, and 2144a may be directly connected to one of the first upper connection lines 2141b, 2142b, 2143b, and 2144b. Also, other lower connection lines may also be directly connected to other upper connection lines.

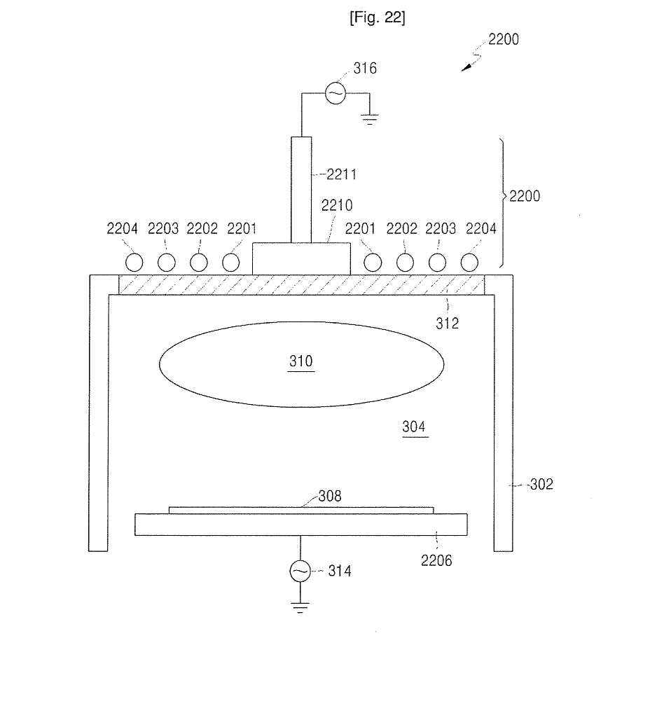

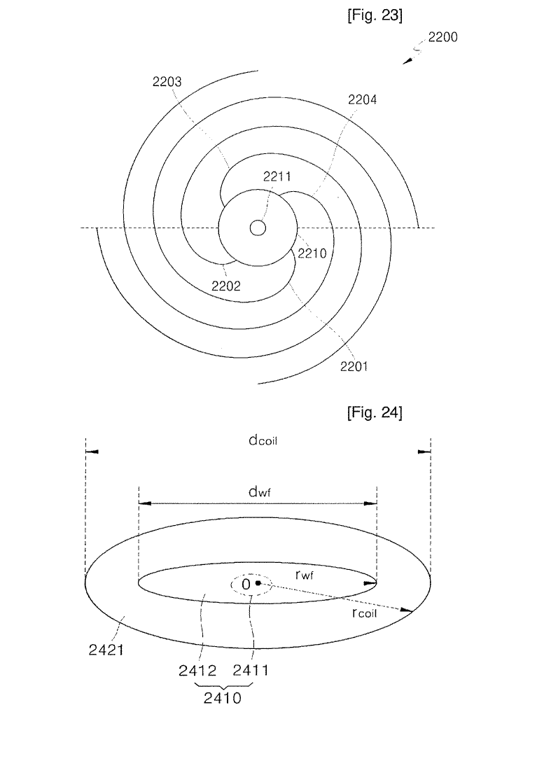

FIG. 22 is a cross-sectional view illustrating a plasma chamber using a plasma source coil in accordance with another preferred embodiment of the present invention. FIG. 23 is a plan view illustrating the plasma source coil shown in FIG. 22. Elements identical to those of FIG. 3 are denoted by the same reference numerals as in FIG. 3, such that their detailed description will herein be omitted for the convenience of description.

Referring to FIGS. 22˜23, the plasma source coil 200 for use in the plasma chamber 2200 includes a plurality of unit coils (e.g., first, second, third, and fourth unit coils 2201, 2202, 2203, and 2204) and a bushing 2210. In more detail, the bushing 2210 is arranged at the center part, and first to unit coils 2201˜2204 are extended from the bushing 2210, and are spirally wound on the circumference of the bushing 2210. Although 4 unit coils are illustrated in FIG. 22, the number of unit coils may be freely selected as necessary. In other words, the number “m” of unit coils may be determined to be an integer greater than “2”. Each of the unit coils 2201, 2202, 2203, and 2204 has a predetermined turning number “n”, and this turning number “n” can be determined to be a positive real number. Namely, the turning number “n” is calculated using a predetermined value of n=a×(b/m) (where “a” and “b” are both positive integers). The bushing 2210 is formed of the same material as the unit coils 2201, 2202, 2203, and 2204. For example, if the unit coils 2201, 2202, 2203, and 2204 are formed of copper, the bushing 2210 is also formed of copper. However, if needed, the bushing 2210 can also be formed of other materials different from those of the unit coils 2201˜2204. It should be noted that the bushing 2210 can also be formed of a conductive material. Although the bushing 2210 is configured in the form of a cylinder having a predetermined radius, and can also take of other forms as necessary.

A support rod 2211 projected in a predetermined direction perpendicular to the top of the bushing 2210 is arranged at the center part of the bushing 2210. The support rod 2211 is also formed of a conductive material such as copper. The support rod 2211 is connected to one terminal of an RF power-supply unit 316. The other terminal of the RF power-supply unit 316 is grounded. The power generated from the RF power-supply unit 316 is applied to first to fourth unit coils 2201˜2204 via the support rod 2211 and the bushing 2210.

According to the plasma source coil having the above-mentioned structure and the plasma chamber using the same, plasma density at the center part is relatively lower than the plasma density at the edge part due to the bushing 2210 disposed at the center part, resulting in uniform distribution of

### ΔCD

. In more detail, more polymer-based by-products are generated at the center part due to the relatively high plasma density at the center part. Since the etching rate is reduced due to the above-mentioned by-products, the

### ΔCD

distribution at the center part is different from the

### ΔCD

distribution at the edge part. The plasma density at the center part is reduced due to the presence of the bushing 2210, and the amount of generated polymer-based by-products is also reduced, such that the

### ΔCD

distribution at the center part and the

### ΔCD

distribution at the edge part are both uniform. Although the above-mentioned plasma source coil and the plasma chamber using the same have the above-mentioned advantages, they have difficulty in more finely adjusting the distribution of

### ΔCD

in the range from the center part to the edge part. Particularly, the above-mentioned disadvantage has been increasingly considered as an important problem due to the increasing capacity of a wafer.

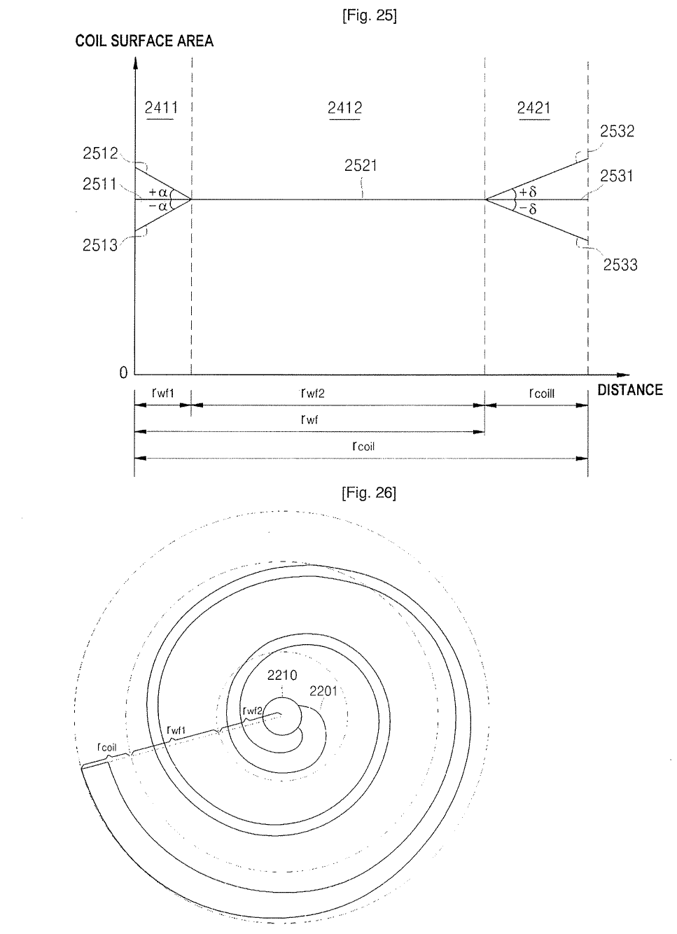

FIG. 24 shows an exemplary distance from the center part to individual edges of a wafer and a plasma source coil to illustrate a plasma source coil in accordance with another preferred embodiment of the present invention. FIG. 25 shows exemplary distribution of a surface area from the center part of a plasma source coil to an edge of the plasma source coil in accordance with another preferred embodiment of the present invention. FIG. 26 shows an exemplary unit coil contained in a plasma source coil in accordance with another preferred embodiment of the present invention. In FIGS. 24˜26, the same elements are denoted by the same reference numerals.

Referring to FIGS. 24˜25, a coil radius r_{coil} from the center part “0” to an edge of a plasma source coil is greater than a wafer radius r_{wf} from the center part “0” to a wafer edge. Therefore, a coil radius d_{coil} of the plasma source coil is greater than the wafer diameter d_{wf}. A wafer area 2410 is classified into a first wafer area 2411 and a second wafer 2412. The first wafer area 2411 is indicative of a circular area having a first wafer radius r_{wf1} from the center part “0”. The second wafer area 2412 is indicative of a circular area enclosing the first wafer area 2411, and has a predetermined width r_{wf2}. The coil edge 2421 is indicative of a circular area enclosing the second wafer area 2412, and has a predetermined width r_{coil1}.

In the case of the first wafer area 2411, individual coil surface areas of a plurality of unit coils contained in the plasma source coil are gradually changed in the range from the center part “0” to the edge part of the first wafer area 2411. In this case, the plasma source coil is configured as shown in FIG. 23. The following description will exemplarily disclose only one of the unit coils for the purpose of illustration. A surface area of the unit coil may be differently changed in individual areas. In the first wafer area 2411, the line denoted by 2511 is indicative of a specific case in which coil surface area is maintained constant, the line denoted by 2512 is indicative of a specific case in which coil surface area is gradually reduced, and the line denoted by 2513 is indicative of a specific case in which coil surface area is gradually increased. In the second wafer area 2412, the line denoted by 2521 is indicative of a specific case in which coil surface area is maintained constant. In the coil edge part 2421, the line denoted by 2531 is indicative of a specific case in which coil surface area is maintained constant, the line denoted by 2532 is indicative of a specific case in which coil surface area is gradually increased, and the line denoted by 2533 is indicative of a specific case in which coil surface area is gradually reduced.

In the first wafer area 2411, the degree of reduction 2512 in coil surface area can be denoted by a predetermined angle

+α
, and the degree of increase 2513 in the coil surface area can be denoted by a predetermined angle
−α
. If the above-mentioned angles
+α
and
−α
are high, this indicates that coil surface area is greatly reduced or increased. If the above-mentioned angles
+α
and
−α
are low, this indicates that coil surface area is slightly reduced or increased. In this way, the degree of increase 2532 in coil surface area in the coil edge area 2421 can be denoted by
+δ
, and the degree of reduction 2533 in coil surface area in the coil edge area 2421 can be denoted by
−δ
. If the above-mentioned angles
+δ
and
−δ
are high, this indicates that coil surface area is greatly increased or reduced. If the above-mentioned angles
+δ
and
−δ
are low, this indicates that coil surface area is slightly increased or reduced.

Referring to FIG. 26, in the case of a unit coil 2201 among a plurality of unit coils, a surface area of the unit coil 2201 is gradually reduced in the first wafer area 2411. The surface area of the unit coil 2201 is maintained constant in the second wafer area 2411. The surface area of the unit coil 2201 is gradually increased in the coil edge area 2421. In this way, a surface area of the unit coil 2201 is differently changed in individual areas, such that plasma density in the plasma chamber can also be changed in various ways. As a result, the distribution of

### ΔCD

in the range from the center part of the wafer and the edge of the wafer can be adjusted in various ways.

In more detail, a signal supplied from an RF power-supply unit is generally indicative of an alternating current (AC) signal. Most AC signals flow along a coil surface due to a skin effect. In this case, a signal flows in a specific area corresponding to a skin depth indicative of a predetermined depth from the coil surface, and this skin depth varies according to changes in the coil surface area. For example, the lower the coil surface area, the lower the coil skin depth. If current capacity is maintained constant and the coil skin depth is reduced, the coil surface depth is also reduced. If the current capacity is maintained constant and the coil skin depth is reduced, current density is increased. In this way, if the current density is increased, plasma density contained in the plasma chamber is also increased. On the contrary, if the coil surface area is increased, the coil skin depth is increased, such that current density is reduced. In this way, if the current density is reduced, the plasma density generated in the plasma chamber is also reduced. Current density is changed with the coil surface area, and plasma density is also changed with the current density. If the plasma density is changed, this indicates that a specific element, e.g., etching rate of an etching process, is changed.

Referring back to FIG. 25, it is assumed that a cross-sectional area of the plasma source coil is sequentially changed in the order of a first reference numeral 2512->a second reference numeral 2521->a third reference numeral 2532. If the cross-sectional area of the plasma source coil is changed as described above, a surface area of a unit coil is gradually reduced in the first wafer area 2411, is maintained constant in the second wafer area 2412, and is then gradually increased in a coil edge part 2421. In more detail, the closer the coil position is to the edge part on the basis of the center part “0”, the higher the plasma density. The plasma density is then maintained constant in the second wafer area 2412. Thereafter, the closer the coil position is to the edge part in the coil edge area 2421, the lower the plasma density. Due to the above-mentioned plasma density distribution, the closer the coil position is to the edge part in the first wafer area 2411, the higher the etching rate. The closer the coil position is to the edge part in the coil edge area 2421, the lower the etching rate. A predetermined etching rate is maintained constant in the second wafer area 2412. Therefore, uneven distribution of

### ΔCD

, which may be generated when etching rate is gradually reduced approaching an edge part of the first wafer area 2411 and is gradually increased approaching an edge part of the coil edge area 2421, can be properly adjusted to uniform distribute

### ΔCD

.

For another example, it is assumed that a cross-sectional area of the plasma source coil is sequentially changed in the order of a first reference numeral 2512->a second reference numeral 2521->a third reference numeral 2532. If the cross-sectional area of the plasma source coil is changed as described above, a cross-sectional area of a unit coil is gradually reduced in the first wafer area 2411, is maintained constant in the second wafer area 2412, and is then gradually reduced in a coil edge area 2421. In more detail, the closer the coil position is to the edge part on the basis of the center part “0”, the higher the plasma density. The plasma density is then maintained constant in the second wafer area 2412. Thereafter, the closer the coil position is to the edge part in the coil edge area 2421, the higher the plasma density. Due to the above-mentioned plasma density distribution, the closer the coil position is to the edge part in the first wafer area 2411, the higher the etching rate. The closer the coil position is to the edge part in the coil edge area 2421, the higher the etching rate. A predetermined etching rate is maintained constant in the second wafer area 2412. Therefore, uneven distribution of

### ΔCD

, which may be generated when etching rate is gradually reduced approaching an edge part of the first wafer area 2411 and is gradually reduced approaching an edge part of the coil edge area 2421, can be properly adjusted to uniform distribute

### ΔCD

. Other examples are equal to the above-mentioned example, such that their detailed description will herein be omitted for the convenience of description, and the above-mentioned principle can also be equally applied to other preferred embodiments of the present invention.

The radius r_{wf1} from the center part “0” of the first wafer area 2411 to the edge part thereof is equal to about 10˜30% of the entire radius of the wafer. The width r_{wf2} of the second wafer area 2412, i.e., the distance from the edge part of the first wafer area 2411 to the edge part of the second wafer area 2412, is equal to about 70˜90% of the entire radius of the wafer. The width r_{coil1} of the coil edge area 2421, i.e., the distance from the edge part of the second wafer area 2412 to the edge part of the coil edge area 2421, is equal to about 30˜50% of the entire radius of the wafer. For example, if a 200 mm wafer is used, the radius r_{wf1} from the center part “0” of the first wafer area 2411 to the edge part thereof is about 1˜3 cm, the width r_{wf2} of the second wafer area 2412 is about 7˜9 cm, and the width r_{coil} of the coil edge part 2421 is about 3˜5 cm. If a 300 mm wafer is used, the radius r_{wf1} from the center part “0” of the first wafer area 2411 to the edge part thereof is about 1.5˜4.5 cm, the width r_{wf2} of the second wafer area 2412 is about 10.5˜13.5 cm, and the width r_{coil1} of the coil edge part 2421 is about 4.5˜7.5 cm. However, the above-mentioned numerical values may be changed as necessary.

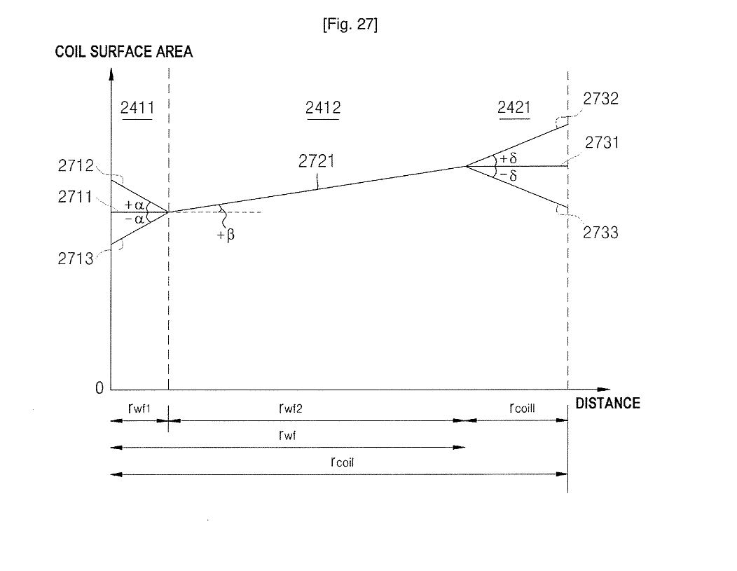

FIG. 27 shows another exemplary distribution of a surface area from the center part of a plasma source coil to an edge of the plasma source coil in accordance with another preferred embodiment of the present invention.

Referring to FIG. 27, in the case of the first wafer area 2411, individual coil surface areas of a plurality of unit coils contained in the plasma source coil are gradually changed in the range from the center part “0” to the edge part of the first wafer area 2411. A surface area of the unit coil may be differently changed in individual areas in the same manner as in FIG. 25. In the first wafer area 2411, the line denoted by 2711 is indicative of a specific case in which coil surface area is maintained constant, the line denoted by 2712 is indicative of a specific case in which coil surface area is gradually reduced, and the line denoted by 2713 is indicative of a specific case in which coil surface area is gradually increased. In the second wafer area 2412, the line denoted by 2721 is indicative of a specific case in which coil surface area is gradually increased approaching the edge part. In the coil edge area 2421, the line denoted by 2731 is indicative of a specific case in which coil surface area is maintained constant, the line denoted by 2732 is indicative of a specific case in which coil surface area is gradually increased approaching the edge part, and the line denoted by 2733 is indicative of a specific case in which coil surface area is gradually reduced approaching the edge part.

In the first wafer area 2411, the degree of reduction 2712 in coil surface area can be denoted by a predetermined angle

+α
and the degree of increase 2713 in the coil surface area can be denoted by a predetermined angle
−α
. If the above-mentioned angles
+α
and
−α
are high, this indicates that coil surface area is greatly reduced or increased. If the above-mentioned angles
+α
and
−α
are low, this indicates that coil surface area is slightly reduced or increased. In this way, the degree of increase 2721 in the coil surface area in the second wafer area 2412 can be denoted by
+β
. If the angle
−β
is high, this indicates that coil surface area is greatly increased. If the angle
+β
is low, this indicates that the coil surface area is slightly increased. In this way, the degree of increase 2732 in the coil surface area in the coil edge part 2421 can be denoted by
+δ
and the degree of reduction 2733 in the coil surface area in the coil edge part 2421 can be denoted by
−δ
. In this case, if the above-mentioned angles
+δ
and
−δ
are high, this indicates that coil surface area is greatly increased or reduced. Otherwise, if the above-mentioned angles
+δ
and
+δ
are low, this indicates that coil surface area is slightly increased or reduced.

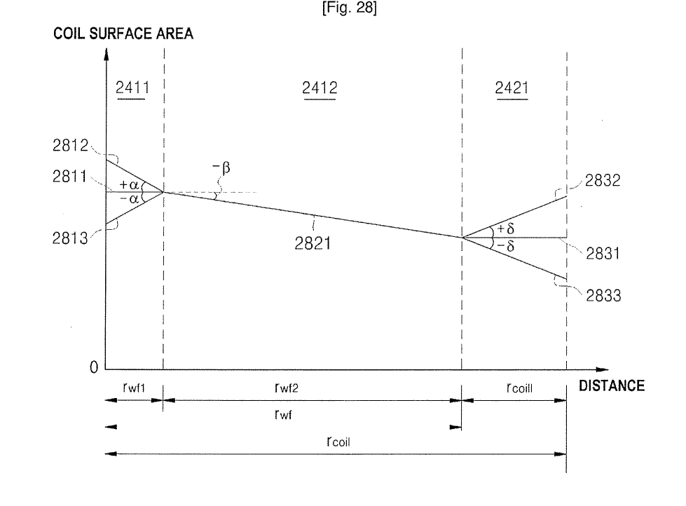

FIG. 28 shows yet another exemplary distribution of a surface area from the center part of a plasma source coil to an edge of the plasma source coil in accordance with another preferred embodiment of the present invention.

Referring to FIG. 28, in the case of the first wafer area 2411, individual coil surface areas of a plurality of unit coils contained in the plasma source coil are gradually changed in the range from the center part “0” to the edge part of the first wafer area 2411. In the first wafer area 2411, the line denoted by 2811 is indicative of a specific case in which coil surface area is maintained constant, the line denoted by 2812 is indicative of a specific case in which coil surface area is gradually reduced, and the line denoted by 2813 is indicative of a specific case in which coil surface area is gradually increased. In the second wafer area 2412, the line denoted by 2821 is indicative of a specific case in which coil surface area decreases approaching the edge part. In the coil edge area 2421, the line denoted by 2831 is indicative of a specific case in which coil surface area is maintained constant, the line denoted by 2832 is indicative of a specific case in which coil surface area is gradually increased approaching the edge part, and the line denoted by 2833 is indicative of a specific case in which coil surface area is gradually reduced approaching the edge part.

In the first wafer area 2411, the degree of reduction 2812 in coil surface area can be denoted by a predetermined angle

+α
, and the degree of increase 2513 in the coil surface area can be denoted by a predetermined angle
−α
. If the above-mentioned angles
+α
and
−α
are high, this indicates that coil surface area is greatly reduced or increased. If the above-mentioned angles
+α
and
−α
are low, this indicates that coil surface area is slightly reduced or increased. In this way, the degree of reduction 2821 in the coil surface area in the second wafer area 2412 can be denoted by
+β
. If the angle
+β
is high, this indicates that coil surface area is greatly increased. If the angle
+β
is low, this indicates that the coil surface area is slightly increased. In this way, the degree of increase 2832 in the coil surface area in the coil edge part 2421 can be denoted by
+δ
, and the degree of reduction 2833 in the coil surface area in the coil edge part 2421 can be denoted by
−δ
. In this case, if the above-mentioned angles
+δ
and
−δ
are high, this indicates that coil surface area is greatly increased or reduced. Otherwise, if the above-mentioned angles
+δ
and
−δ
are low, this indicates that coil surface area is slightly increased or reduced.

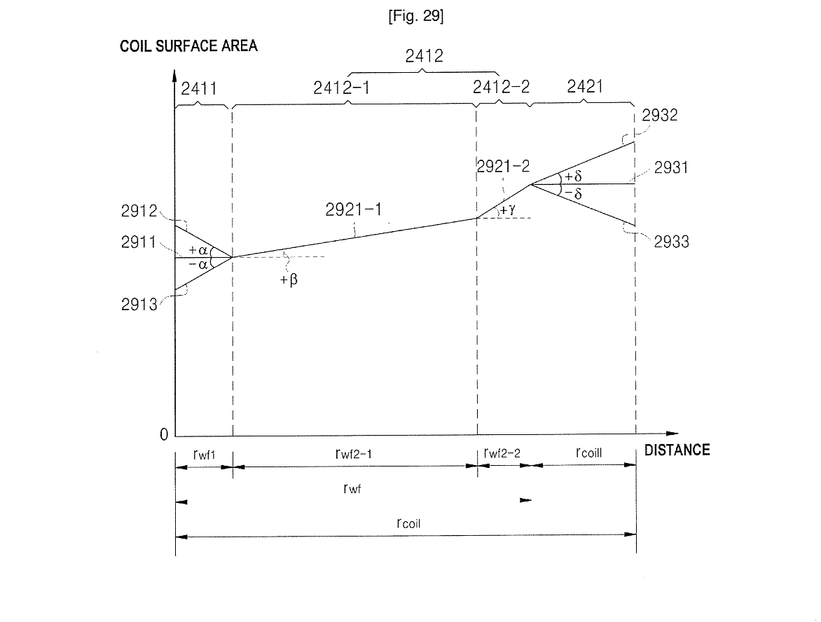

FIG. 29 shows yet another exemplary distribution of a surface area from the center part of a plasma source coil to an edge of the plasma source coil in accordance with another preferred embodiment of the present invention. Elements identical to those of FIG. 27 are denoted by the same reference numerals as in FIG. 27.

Referring to FIG. 29, the second wafer area 2412 contained in the plasma source coil according to the present invention is divided into two wafer areas 2412-1 and 2412-2, differently from the plasma source coil shown in FIG. 27. In more detail, a first area 2412-1 of the second wafer area 2412 is indicative of a circular area adjacent to the edge part of the first wafer area 2411, and has a predetermined radius r_{wf2-1}. A second area 2412-2 of the second wafer area 2412 is indicative of a circular area enclosing the second wafer area 2412-1, and has a predetermined radius r_{wf2-2}. The sum of a width r_{wf2-1} of the first area 2412-1 of the second wafer area 2412 and a width rwf2-2 of the second area 2412-2 of the second wafer area 2412 is equal to the width r_{wf2} of the second wafer area 2412. The width r_{wf2-2} of the first area 2412-1 of the second wafer area 2412 is about 60˜90% of a total width of the second wafer area 2412. For example, if a 200 mm wafer is used, the width r_{wf2-2} is about 4.2˜8.1 cm. If a 300 mm wafer is used, the width r_{wf2-2} is about 6.3˜12.2 cm.

A surface area of the unit coil in the first area 2412-1 of the second wafer area 2412 is gradually increased as denoted by 2921-1, and the degree of increase in the surface area of the unit coil can be denoted by a predetermined angle

+β
. A surface area of the unit coil in the second area 2412-2 of the second wafer area 2412 is gradually increased as denoted by 2921-2, is more rapidly increased than that in the first area 2412-1 of the second wafer area 2412, and the degree of increase in the surface area of the unit coil can be denoted by a predetermined angle
+γ
. Although the coil surface area increases approaching the edge part of each of the first area 2412-1 and the second area 2412-2 as shown in FIG. 29, it should be noted that the coil surface area may decreases approaching the edge part, and the degree of increase or reduction may also be variable as necessary. The plasma source coil according to the present invention can finely adjust plasma density at a wafer edge where it is very difficult to control CD.

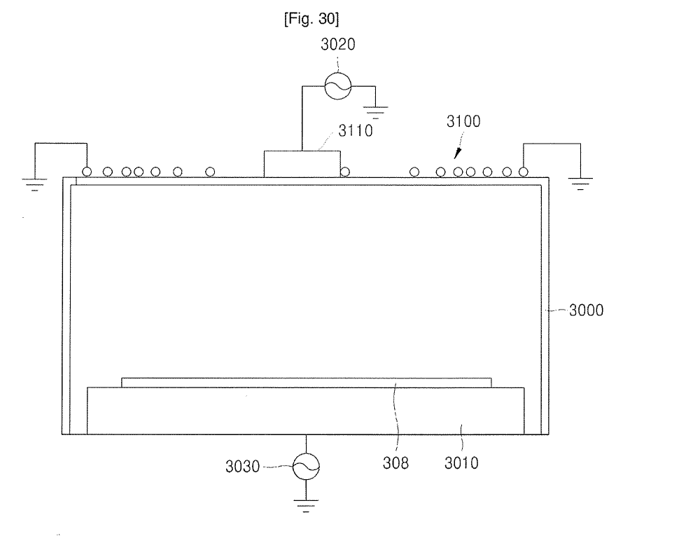

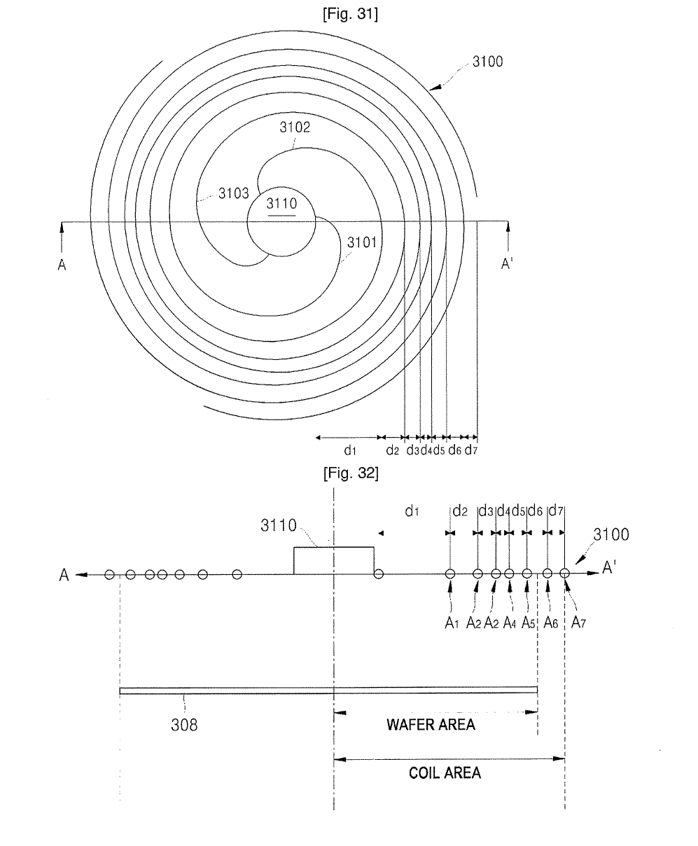

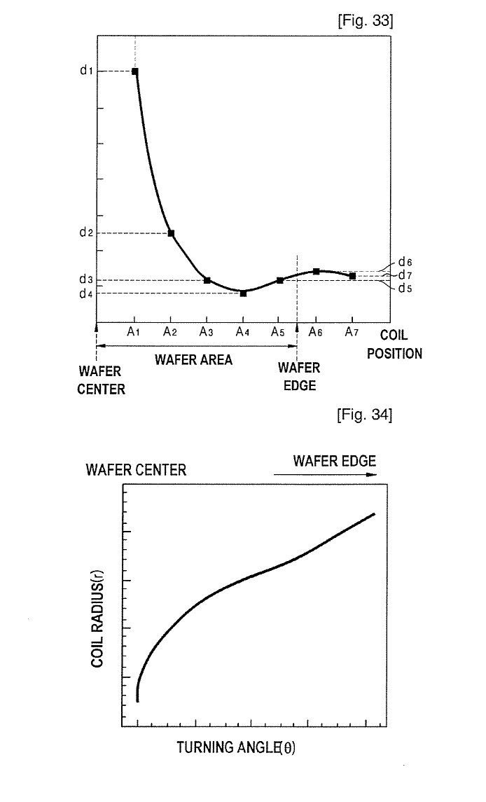

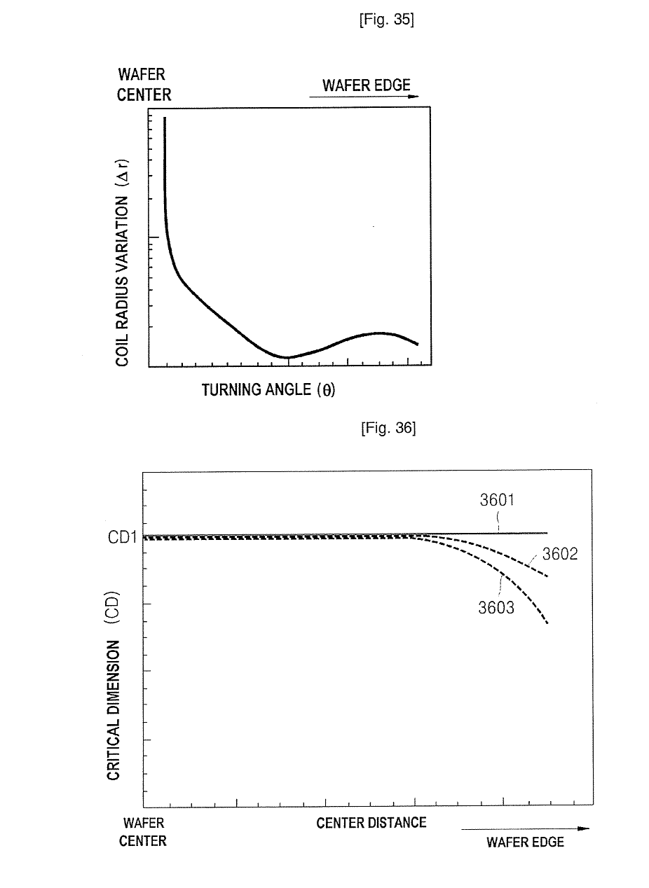

FIG. 30 is a cross-sectional view illustrating a plasma chamber using a plasma source coil in accordance with yet another preferred embodiment of the present invention. FIG. 31 is a plan view illustrating a plasma source coil in accordance with yet another preferred embodiment of the present invention. FIG. 32 is a cross-sectional view illustrating the plasma source coil taken along the line A-A′ of FIG. 31. FIG. 33 is a graph illustrating variation in distance between coils in the direction of a wafer edge of the plasma source coil shown in FIGS. 31˜32. FIG. 34 is a graph illustrating a coil radius depending on a turning angle of the plasma source coil of FIGS. 31˜32. FIG. 35 is a graph illustrating variation in the coil radius depending on the turning angle of the plasma source coil of FIGS. 31˜32. FIG. 36 is a graph illustrating CD distribution on a wafer due to the introduction of a plasma source coil in accordance with yet another preferred embodiment of the present invention.

Referring to FIGS. 30˜31, a plasma chamber acting as a dry etching device includes a reaction chamber 3000 including a plasma process space therein. The internal space of the reaction chamber 3000 is isolated from an external part, and is maintained under high vacuum, such that etching and other processes can be performed within the reaction chamber 3000.

The reaction chamber 300 includes a semiconductor substrate to be processed, for example, a substrate support 3010 for supporting a wafer 308, and an ESC, etc., in its lower space. A bias power unit 3030 for transmitting bias power to a back surface of the wafer 308 is electrically connected to the substrate support 3010. The bias power unit 3030 includes an RF power-supply unit.

A plasma source coil 3100 capable of forming plasma is arranged at an external part of an upper part of the reaction chamber 3000. As shown in FIG. 31, the plasma source coil 3100 includes a coil bushing 3110 arranged at the center part, and at least two unit coils 3101, 3102, and 3103 spirally wound on a circumference of the coil bushing 3110.

Although the preferred embodiment shows a bundle of three unit coils 3101, 3102, and 3103 which are extended from the coil bushing 3110 for the purpose of illustration, it should be noted that the number of unit coils may be less or greater than “3” as necessary. In other words, the number of unit coils may be determined to be an integer greater than “2”, and individual unit coils 3101, 3102, and 3103 may be spirally wound on a flat surface in the vicinity of the coil bushing 3110 n times (also called a turning number of n).

In this case, a turning number “n” may be determined to be a positive integer. The turning number “n” of individual unit coils 3101, 3102, and 3103 is not always set to an integer. For example, the turning number “n” of individual unit coils 3101˜3103 may be determined to be a turning number of 1.25. Nevertheless, it is preferable that the number “m” of unit coils may be equal to or greater than “3”, and that the turning number “n” be less than “3”. Indeed, the number of unit coils may be determined to be a plural number (e.g., “5” or over) such that a plurality of unit coils equal to the determined plural number can be arranged in the vicinity of the coil bushing 3110. Also, the turning number may also be determined to be a plural number under allowable turning number or space. Nevertheless, the preferred embodiment of the present invention shows a specific case in which the number “m” of unit coils is preferably determined to be “3” and the turning number “n” is preferably determined to be “7/3” in FIG. 31 for the purpose of illustration, and its detailed description will hereinafter be described with reference to FIG. 31.

The coil bushing 3110 is formed of the same material as the unit coils 3101, 3102, and 3103. For example, if the unit coils 3101, 3102, and 3103 are formed of copper, the coil bushing 3110 may also be formed of copper. However, if needed, the coil bushing 3110 can also be formed of other materials different from those of the unit coils 3101, 3102, and 3103. However, there is a need to use a conductive material although the coil bushing 3110 is formed of other materials.

A source power unit 3020 for providing a plasma source power to generate plasma is electrically connected to the center part of the coil bushing 3110. The source power-unit 3020 may be composed of an RF power-supply unit. Therefore, an RF power signal of the source power unit 3020 is applied to unit coils 3101˜3103 via the coil bushing 3110. Other ends of the unit coils 3101˜3103 are preferably grounded.

In the case of the plasma chamber shown in FIG. 30 using the above-mentioned plasma chamber, an RF current signal generated from the source power unit 3020 flows to individual unit coils 3101˜3103 via the coil bushing 3110, such that the unit coils 3101˜3103 generate an RF magnetic field. By the above-mentioned magnetic field, an induced electric field is generated in the chamber 3000 according to Faraday's law of electromagnetic induction. If specific gas, e.g., etching reaction gas, is supplied in the chamber 3000 along with the above-mentioned induced magnetic field, plasma is generated and maintained. A semiconductor etching process is performed on the wafer 308 using the above-mentioned induction plasma. In this case, the introduction of the coil bushing 3110 can enhance a CCP (Capacitively Coupled Plasma) unique effect according to management areas of the coil bushing 3110. This is a representative characteristic of Adaptively Coupled Plasma (ACP) for use in the present invention.

In the case of a plasma etching device using a conventional ICP (Inductively Coupled Plasma) coil, CD distribution on the wafer may be uneven when the etching process is performed on the wafer using the plasma generated in the chamber. The graph denoted by the reference number 3603 from among a plurality of graphs shown in FIG. 36 indicates CD distribution which is acquired from the wafer when a conventional ICP coil is used and each distance among wound coils is maintained constant. In this case, the CD distribution is changed approaching the edge part of the wafer. For example, the CD distribution is gradually reduced approaching the edge part of the wafer.

In order to solve the above-mentioned unevenness of the CD distribution, modification of the shape of the conventional ICP coil, so as to reduce the distance among coils approaching the edge part, has been previously attempted. Nevertheless, if the shape of the conventional ICP coil is modified, the degree of uneven CD distribution can be slightly reduced as denoted by 3602 in FIG. 36, but a CD value is relatively low at the edge part of the wafer, such that the unevenness of CD distribution remains.

In order to solve the above-mentioned unevenness of the CD distribution on the wafer, the plasma source coil 3100 according to the present invention uses a coil bushing 3110. As shown in FIG. 32, individual distances among coils 3100 are gradually reduced as the distance from the coil bushing 3110 increases, and are then gradually increased in the vicinity of the edge part of the coil 3100. Since distances among the coils 3100 are adjusted as described above, CDs capable of satisfying a reference CD1 can be uniformly distributed over the entire wafer, as denoted by 3601 in FIG. 36.

A CD of a pattern formed on the wafer 308 is affected by a variety of elements introduced to perform a patterning etching process, for example, plasma distribution, etching gas type, and process temperature, etc. In this case, the present invention provides a method for systemically changing the structure of the plasma source coil 3100 capable of directly affecting the plasma distribution, such that uniform CD distribution on the wafer can be achieved.

In more detail, the plasma source coil 3100 according to the present invention includes the coil bushing 3110 at the center part thereof, such that it can generate the CCP effect at an area occupied by the coil bushing 3110. As shown in FIG. 32, the longest distance of individual distances among coils 3100 is provided at the center part, is gradually reduced approaching the edge part, and is then slightly increased in the vicinity of the edge part. In more detail, the distance among coils 3100 is reduced in the form of d₁>d₂>d₃>d₄, and is then increased in the form of d₄≦d₅≦d₆. In this case, the distance among the coils 3100 may be slightly reduced at the outermost edge, as denoted by d₆>d₇. In this way, the distance among the coils 3100 can be adjusted as stated above. The reason why the distance among the coils 3100 is slightly reduced at the outermost edge as denoted by d₆>d₇ is to minimize the destruction of symmetrical characteristics depending on a turning angle at the outermost edge due to the severed coils 3100.

Individual distances among coils 3100 according to different positions spaced apart from the center part of the coil bushing 3110, i.e., a graph for illustrating a relationship between individual coil positions and individual distances among coils, can be drawn as shown in FIG. 33. Provided that individual coil positions from the center part of the coil bushing 3110 are sequentially determined to be A₁->A₂->A₃->A₄->A₅->A₆->A₇, individual distances from the preceding coils at individual coil positions are determined to be d₁, d₂, d₃, d₄, d₅, d₆, and d₇, respectively, and variation in the distance among coils is given in the form of a graph shown in FIG. 33.

In the case of a single coil 3101, as the single coil 3101 is spirally wound, the distance between the single coil 3101 and the center part is gradually increased. In this case, the variation in coil radius

γ
at individual positions is shown in FIG. 34. Namely, if the coil radius
γ
is abruptly increased as a turning angle
θ
by which the coil 3101 is wound on polar coordinates, the coil radius
γ
is abruptly increased during an initial time, the degree of increase in the coil radius
γ
is reduced, and is then increased, as shown in FIG. 34.

The above-mentioned variation in the coil radius

γ
can be easily seen from FIG. 35 in which variation in turning angle
θ
is shown. In more detail, the degree of variation in the coil radius
γ
is firstly very abruptly reduced as the turning angle
θ
increases, is secondly slightly reduced, and is then increased, as shown in FIG. 35. In addition, the degree of variation in the coil radius
γ
is finally reduced at the outermost position of the wafer. The graph of FIG. 34 shows variation in the coil radius
γ
depicted on polar coordinates. In this case, the coil radius variation is changed according to the turning angle
θ
. The graph of FIG. 35 uses a logarithmic scale to more fully describe the shape of variation in the coil radius
γ
depending on the turning angle
θ
. In FIG. 35, the value of the variation of the coil radius
γ
is denoted by a differential value.

If the above-mentioned plasma source coil capable of adjusting the coil distance “d” is used as described above, substantial etching environments on the wafer 308 can be uniformly applied to the entire wafer 308. Therefore, the CD distribution on the wafer 308 can be uniformly implemented as denoted by 3601 in FIG. 36.

In the meantime, it is preferable that an area of the plasma source coil 3100 according to the present invention, i.e., the coil area, is greater than the area of the wafer 308 shown in FIG. 32, such that the uniformity of etching environments on the wafer 308 can also be maintained at the edge of the wafer 308. In more detail, plasma reaches the outside of the wafer 308's area (hereinafter referred to as the wafer area), such that a substantial plasma state in the outermost part of the wafer area can be stabilized. In this case, it is preferable for the coil area to be greater than the wafer area by about 50% or less. Preferably, the coil distance “d” must be controlled so that a coil position at a specific point at which the coil distance “d” is again increased, e.g., at the point A₅, must be included in the wafer area. In this case, the point A₅ at which a minimum coil distance “d” is provided may be positioned in a predetermined area which occupies about 70˜90% of a distance from the center part to the edge part in the wafer area.

As the distance from the center part to the edge part in the plasma source coil 3100 gradually increases, a distance among coils is more finely adjusted, such that a substantial fabrication environment, e.g., an etching environment, can be uniformly applied to the entire wafer 308. The fabrication environment or the etching environment capable of substantially affecting a surface on the wafer 308 can be affected by a variety of components, e.g., process temperature, plasma density distribution, and process gas type, etc.

Particularly, the plasma density distribution can be considered to be the most important factor in the etching environment. Substantially, the plasma density distribution is firstly affected by the plasma generation environment, for example, the induced electric field distribution, etc. The present invention can control the above-mentioned induced electric field distribution using the coil bushing 3110 and a plurality of unit coils 3101˜3103 extended from the coil bushing 3110 while being spirally wound. According to the present invention, as the distance from the center part to the edge part in the plasma source coil 3100 gradually increases, the distance among coils 31016˜3103 is gradually reduced and is then increased. The present invention allows a substantial etching environment on the wafer 308 to be uniformly distributed over the entire wafer 308, resulting in uniform distribution of CD over the entire wafer 308.

### INDUSTRIAL APPLICABILITY

As apparent from the above description, the present invention can be applied to a semiconductor using a plasma chamber, and other devices and processes in semiconductor related fields.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A plasma source coil comprising:
a bushing arranged at a center part; and
a plurality of unit coils arranged in the form of a concentric circle from a circumference of the bushing on the basis of the bushing,
wherein one end of each unit coil and one end of the bushing are commonly connected to a power-supply terminal, and the other end of each unit coil and the other end of the bushing are commonly connected to a ground terminal.

2. The plasma source coil according to claim 1, wherein the bushing is formed of a conductive material.

3. The plasma source coil according to claim 1, wherein the plurality of unit coils are each configured in the form of a circle.

4. The plasma source coil according to claim 1, wherein the plurality of unit coils have a convex-type structure so that their position is lowered in proportion to a distance from the bushing.

5. The plasma source coil according to claim 4, wherein at least two unit coils arranged at the outermost position from among the plurality of unit coils are arranged on the same plane.

6. The plasma source coil according to claim 1, wherein the plurality of unit coils have a concave-type structure so that their position is elevated in proportion to a distance from the bushing.

7. The plasma chamber according to claim 6, wherein at least two unit coils arranged at the outermost position from among the plurality of unit coils are arranged on the same plane.

8. A plasma source coil comprising:
a plurality of lower unit coils arranged in the form of a concentric circle on a first plane in a lower part; and
a plurality of upper unit coils arranged in the form of a concentric circle on a second plane in an upper part,
wherein one ends of the lower unit coils are commonly connected to a power-supply terminal and the other ends thereof are commonly connected to a ground terminal, and one ends of the upper unit coils are commonly connected to the power-supply terminal and the other ends thereof are commonly connected to the ground terminal.

9. The plasma source coil according to claim 8, wherein a distance among the lower unit coils and a distance among the upper unit coils are each indicative of 0.5˜2 cm.

10. The plasma source coil according to claim 8, wherein the lower unit coils and the upper unit coils are connected to each other via connection lines connected to the power-supply terminal and the other connection lines connected to the ground terminal.

11. A plasma source coil comprising:
a bushing vertically arranged in the form of a cylinder at a center part;
a plurality of lower unit coils arranged in the form of a concentric circle on a first plane where the bottom of the bushing is located; and
a plurality of upper unit coils arranged in the form of a concentric circle on a second plane where the top of the bushing is located,
wherein one ends of the lower unit coils are commonly connected to a power-supply terminal and the other ends thereof are commonly connected to a ground terminal, and one ends of the upper unit coils are commonly connected to the power-supply terminal and the other ends thereof are commonly connected to the ground terminal.

12. The plasma chamber according to claim 11, wherein the bushing is connected to the power-supply terminal and the ground terminal.

13. The plasma source coil according to claim 11, wherein a distance among the lower unit coils and a distance among the upper unit coils are each indicative of 0.5˜2 cm.

14. The plasma source coil according to claim 11, wherein the lower unit coils and the upper unit coils are connected to each other via connection lines connected to the power-supply terminal and the other connection lines connected to the ground terminal.

15. A plasma source coil comprising:
a plurality of unit coils arranged in the form of concentric circles having different radiuses while having a common center part,
wherein one ends of the unit coils are commonly connected to a power-supply unit, the other ends thereof are commonly connected to a ground terminal, and the unit coils are connected to each other via at least one connection line.

16. A plasma source coil comprising:
a plurality of unit coils arranged in the form of concentric circles having different radiuses on the basis of a bushing arranged at a center part,
wherein one ends of the unit coils are commonly connected to a power-supply unit, the other ends thereof are commonly connected to a ground terminal, and the unit coils are connected to each other via at least one connection line.

17. The plasma source coil according to claim 16, wherein the plurality of unit coils have a convex-type structure so that their position is lowered in proportion to a distance from the bushing.

18. The plasma source coil according to claim 16, wherein the plurality of unit coils have a concave-type structure so that their position is elevated in proportion to a distance from the bushing.

19. A plasma source coil comprising:
a plurality of lower unit coils arranged in the form of a concentric circle on a first plane in a lower part; and
a plurality of upper unit coils arranged in the form of a concentric circle on a second plane in an upper part,
wherein one ends of the lower unit coils are commonly connected to a power-supply terminal and the other ends thereof are commonly connected to a ground terminal, one ends of the upper unit coils are commonly connected to the power-supply terminal and the other ends thereof are commonly connected to the ground terminal, and
the lower unit coils are connected to each other via at least one lower connection line, and the upper unit coils are connected to each other via at least one upper connection line.

20. A plasma source coil comprising:
a bushing vertically arranged in the form of a cylinder at a center part;
a plurality of lower unit coils arranged in the form of a concentric circle on a first plane where the bottom of the bushing is located; and
a plurality of upper unit coils arranged in the form of a concentric circle on a second plane where the top of the bushing is located,
wherein one ends of the lower unit coils are commonly connected to a power-supply terminal and the other ends thereof are commonly connected to a ground terminal, and one ends of the upper unit coils are commonly connected to the power-supply terminal and the other ends thereof are commonly connected to the ground terminal, and
the lower unit coils are connected to each other via at least one lower connection line, and the upper unit coils are connected to each other via at least one upper connection line.

21. A plasma chamber comprising:
an exterior wall and a dome for defining a reaction space in which plasma is formed;
a support arranged at a lower part of the reaction space to support a semiconductor wafer to be processed; and
a plasma source coil including a bushing arranged at a center part, a plurality of unit coils arranged in the form of a concentric circle from a circumference of the bushing on the basis of the bushing, wherein one end of each unit coil and one end of the bushing are commonly connected to a power-supply terminal, and the other end of each unit coil and the other end of the bushing are commonly connected to a ground terminal.

22. A plasma source coil comprising:
a bushing arranged at a center part; and
a plurality of unit coils, which are extended from the bushing, and are spirally wound on the bushing,
wherein the unit coils have different surface areas in a first wafer area having a predetermined radius from a center part, a second wafer area enclosing the first wafer area, and a coil edge area enclosing the second wafer area.

23. The plasma source coil according to claim 22, wherein the unit coils are arranged to have a predetermined turning number “n” calculated using a predetermined equation of n=a×(b/m) (where “a” and “b” are both positive integers, and “m” is indicative of the number of unit coils corresponding to an integer greater than “2”).

24. The plasma source coil according to claim 22, wherein the surface areas of the unit coils are maintained constant, are gradually reduced, or are gradually increased, as a distance to an edge part in the first wafer area decreases.

25. The plasma source coil according to claim 22, wherein the surface areas of the unit coils are gradually increased, are maintained constant, or are gradually reduced, as a distance to an edge part in the second wafer area decreases.

26. The plasma source coil according to claim 22, wherein the surface areas of the unit coils are maintained constant, are gradually reduced, are gradually increased, or are gradually reduced, as a distance to an edge part in the coil edge area decreases.

27. The plasma source coil according to claim 22, wherein the first wafer area and the second wafer area overlap a wafer surface to be processed.

28. The plasma source coil according to claim 22, wherein a radius from a center part of the first wafer area to an edge part thereof is equal to or less than about 10˜30% of an entire radius of a wafer, a width of the second wafer area is equal to about 70˜90% of an entire radius of the wafer, and a width of the coil edge area is equal to about 30˜50% of an entire radius of the wafer.

29. The plasma source coil according to claim 22, wherein the second wafer area includes a first area adjacent to the first wafer area and a second area adjacent to the coil edge area.

30. The plasma source coil according to claim 29, wherein the degree of variation in surface area of each unit coil in the first area of the second wafer area is different from that in the second area of the second wafer area.

31. The plasma source coil according to claim 29, wherein a width of the first area of the second wafer area is about 60˜90% of a total width of the second wafer area, and a width of the second area of the second wafer area is about 10˜40% of the total width of the second wafer area.

32. A plasma chamber comprising:
an exterior wall and a dome for defining a reaction space in which plasma is formed;
a support arranged at a lower part of the reaction space to support a semiconductor wafer to be processed;
a plasma source coil including a bushing arranged at a center part, a plurality of unit coils extended from the bushing while being spirally wound on the bushing,
wherein the unit coils have different surface areas in a first wafer area having a predetermined radius from the center part on the dome, a second wafer area enclosing the first wafer area, and a coil edge area enclosing the second wafer area;
a support rod arranged at a predetermined area of a center part of the bushing; and
a power-supply unit connected to the support rod to provide the plasma source coil with power.

33. The plasma chamber according to claim 32, wherein the unit coils are arranged to have a predetermined turning number “n” calculated using a predetermined equation of n=a×(b/m) (where “a” and “b” are both positive integers, and “m” is indicative of the number of unit coils corresponding to an integer greater than “2”).

34. The plasma chamber according to claim 32, wherein the surface areas of the unit coils are maintained constant, are gradually reduced, or are gradually increased, as a distance to an edge part in the first wafer area decreases.

35. The plasma chamber according to claim 32, wherein the surface areas of the unit coils are gradually increased, are maintained constant, or are gradually reduced, as a distance to an edge part in the second wafer area decreases.

36. The plasma chamber according to claim 32, wherein the surface areas of the unit coils are maintained constant, are gradually reduced, are gradually increased, or are gradually reduced, as a distance to an edge part in the coil edge area decreases.

37. The plasma chamber according to claim 32, wherein the first wafer area and the second wafer area overlap a wafer surface to be processed.

38. The plasma chamber according to claim 32, wherein a radius from a center part of the first wafer area to an edge part thereof is equal to or less than about 10˜30% of an entire radius of a wafer, a width of the second wafer area is equal to about 70˜90% of an entire radius of the wafer, and a width of the coil edge area is equal to about 30˜50% of an entire radius of the wafer.

39. The plasma chamber according to claim 32, wherein the second wafer area includes a first area adjacent to the first wafer area and a second area adjacent to the coil edge area.

40. The plasma chamber according to claim 39, wherein the degree of variation in surface area of each unit coil in the first area of the second wafer area is different from that in the second area of the second wafer area.

41. The plasma source coil according to claim 39, wherein a width of the first area of the second wafer area is about 60˜90% of a total width of the second wafer area, and a width of the second area of the second wafer area is about 10˜40% of the total width of the second wafer area.

42. A plasma apparatus comprising:
a process chamber including a wafer;
a bias power unit for providing a back surface of the wafer with bias power;
a plasma source coil structure disposed at the outside of an upper part of the process chamber to convert reaction gas contained in the process chamber into plasma, including: a coil bushing at a center part, and at least two unit coils which are extended from the coil bushing, are spirally wound on the coil bushing such that a distance between a coil positioned at a specific radial point and the other coil adjacent to the coil is gradually reduced and is then increased, as a distance from the center part to a radial edge increases; and
a source power unit for providing the plasma source coil structure with source power for generating the plasma.

43. The plasma apparatus according to claim 42, wherein the unit coils contained in the plasma source coil structure are wound on the coil bushing at a predetermined turning number of 1 or more.

44. The plasma apparatus according to claim 42, wherein an area of the plasma source coil structure is greater than an area of the wafer by about 50% or less.

45. The plasma apparatus according to claim 44, wherein the unit coils are wound to allow a specific position capable of providing a minimum distance among the unit coils to be included in the wafer area.

46. The plasma apparatus according to claim 45, wherein the specific position having the minimum distance among the coils is positioned adjacent to an edge part of the wafer area, whereby an area in which the distance among the coils is re-increased after passing through the specific position is less than the other area in which the distance among the coils is reduced.
